(19) United States
(12) Patent Application Publication
(10) Pub. No.: US 2024/0373724 A1
(43) Pub. Date: Nov. 7, 2024

(54) LIGHT EMITTING DEVICE

(71) Applicant: Japan Display Inc., Tokyo (JP)

(72) Inventor: Masumi NISHIMURA, Tokyo (JP)

(73) Assignee: Japan Display Inc., Tokyo (JP)

(21) Appl. No.: 18/773,980

(22) Filed: Jul. 16, 2024

Related U.S. Application Data
(63) Continuation of application No. PCT/JP2022/043048, filed on Nov. 21, 2022.

(30) Foreign Application Priority Data
Jan. 28, 2022 (JP) 2022-011853

(51) Int. Cl. H10K 59/80; H10K 59/122

(52) U.S. Cl. CPC H10K 59/878; H10K 59/122

(57) ABSTRACT

A light emitting device includes a substrate, a partition wall defining a plurality of pixels in a matrix over the substrate, a reflective layer covering the partition wall, and an insulating layer covering the reflective layer. Each of the plurality of pixels arranged in a matrix includes a conductive alignment layer over the substrate, a semiconductor layer containing gallium nitride over the conductive alignment layer, a light emitting layer over the semiconductor layer, and an electrode layer over the light emitting layer. A distance from an upper surface of the substrate to an upper surface of the reflective layer in a region overlapping the partition wall is greater than a distance from the upper surface of the substrate to an upper surface of the light emitting layer in a region not overlapping the partition wall.

### CROSS-REFERENCE TO RELATED APPLICATIONS

This application is a Continuation of International Patent Application No. PCT/JP2022/043048, filed on Nov. 21, 2022, which claims the benefit of priority to Japanese Patent Application No. 2022-011853, filed on Jan. 28, 2022, the entire contents of which are incorporated herein by reference.

### FIELD

An embodiment of the present invention relates to a light emitting device including gallium nitride. Further, an embodiment of the present invention relates to a light emitting device formation substrate on which a plurality of light emitting devices including gallium nitride are formed.

### BACKGROUND

Gallium nitride (GaN) is characterized as a direct bandgap semiconductor with a large bandgap. This feature of gallium nitride is utilized and a light emitting diode (LED) using a gallium nitride film has already been in practical use. The gallium nitride film for the LED is generally formed on a sapphire substrate at a high temperature of 800 degrees to 1000 degrees using MOCVD (Metal Organic Chemical Vapor Deposition) or HVPE (Hydride Vapor Phase Epitaxy).

In recent years, the development of a so-called micro LED display device or a mini-LED display device in which minute micro LEDs are mounted in pixels on a circuit substrate is proceeding as a next-generation display device. The micro LED display device or the mini-LED display device has high efficiency, high brightness and high reliability. Such a micro LED display device or a mini-LED display device is manufactured by transferring a LED chip to a backplane on which a transistor using an oxide semiconductor or low-temperature polysilicon is formed (for example, see U.S. Pat. No. 8,791,474).

### SUMMARY

A light emitting device according to an embodiment of the present invention includes a substrate, a partition wall over the substrate, a reflective layer covering the partition wall, and an insulating layer covering the reflective layer. The partition wall defines a plurality of pixels in a matrix in a first direction and in a second direction orthogonal to the first direction. Each of the plurality of pixels arranged in a matrix includes a conductive alignment layer over the substrate, a semiconductor layer containing gallium nitride over the conductive alignment layer, a light emitting layer over the semiconductor layer, and an electrode layer over the light emitting layer. A distance from an upper surface of the substrate to an upper surface of the reflective layer in a region overlapping the partition wall is greater than a distance from the upper surface of the substrate to an upper surface of the light emitting layer in a region not overlapping the partition wall.

A light emitting device according to an embodiment of the present invention includes a substrate, a partition wall over the substrate, a reflective layer covering the partition wall, and an insulating layer covering the reflective layer. The partition wall defines a plurality of pixels in a matrix in a first direction and in a second direction orthogonal to the first direction. Each of the plurality of pixels arranged in a matrix includes an insulating alignment layer over the substrate, a semiconductor layer containing gallium nitride over the insulating alignment layer, a light emitting layer over the semiconductor layer, and a first electrode layer over the light emitting layer. A distance from an upper surface of the substrate to an upper surface of the reflective layer in a region overlapping the partition wall is greater than a distance from the upper surface of the substrate to an upper surface of the light emitting layer in a region not overlapping the partition wall.

### BRIEF DESCRIPTION OF DRAWINGS

FIG. 1 is a schematic diagram showing a configuration of a light emitting device according to an embodiment of the present invention.

FIG. 2A is a schematic cross-sectional view showing a configuration of a light emitting device according to an embodiment of the present invention.

FIG. 2B is a schematic cross-sectional view showing a configuration of a light emitting device according to an embodiment of the present invention.

FIG. 3 is a schematic plan view showing a configuration of a light emitting device according to an embodiment of the present invention.

FIG. 4A is a schematic cross-sectional view showing a configuration of a light emitting device according to an embodiment of the present invention.

FIG. 4B is a schematic cross-sectional view showing a configuration of a light emitting device according to an embodiment of the present invention.

FIG. 5A is a schematic cross-sectional view showing a configuration of a light emitting device according to an embodiment of the present invention.

FIG. 5B is a schematic cross-sectional view showing a configuration of a light emitting device according to an embodiment of the present invention.

FIG. 6A is a schematic cross-sectional view showing a configuration of a light emitting device according to an embodiment of the present invention.

FIG. 6B is a schematic cross-sectional view showing a configuration of a light emitting device according to an embodiment of the present invention.

FIG. 7A is a schematic cross-sectional view showing a configuration of a light emitting device according to an embodiment of the present invention.

FIG. 7B is a schematic cross-sectional view showing a configuration of a light emitting device according to an embodiment of the present invention.

FIG. 8A is a schematic cross-sectional view showing a configuration of a light emitting device according to an embodiment of the present invention.

FIG. 8B is a schematic cross-sectional view showing a configuration of a light emitting device according to an embodiment of the present invention.

FIG. 9A is a schematic cross-sectional view showing a method for manufacturing a light emitting device according to an embodiment of the present invention.

FIG. 9B is a schematic cross-sectional view showing a method for manufacturing a light emitting device according to an embodiment of the present invention.

FIG. 9C is a schematic cross-sectional view showing a method for manufacturing a light emitting device according to an embodiment of the present invention.

FIG. 9D is a schematic cross-sectional view showing a method for manufacturing a light emitting device according to an embodiment of the present invention.

FIG. 9E is a schematic cross-sectional view showing a method for manufacturing a light emitting device according to an embodiment of the present invention.

FIG. 10A is a schematic cross-sectional view showing a configuration of a light emitting device according to an embodiment of the present invention.

FIG. 10B is a schematic cross-sectional view showing a configuration of a light emitting device according to an embodiment of the present invention.

FIG. 11A is a schematic cross-sectional view showing a configuration of a light emitting device according to an embodiment of the present invention.

FIG. 11B is a schematic cross-sectional view showing a configuration of a light emitting device according to an embodiment of the present invention.

FIG. 12A is a schematic cross-sectional view showing a configuration of a light emitting device according to an embodiment of the present invention.

FIG. 12B is a schematic cross-sectional view showing a configuration of a light emitting device according to an embodiment of the present invention.

FIG. 13A is a schematic cross-sectional view showing a configuration of a light emitting device according to an embodiment of the present invention.

FIG. 13B is a schematic cross-sectional view showing a configuration of a light emitting device according to an embodiment of the present invention.

FIG. 14A is a schematic cross-sectional view showing a method for manufacturing a light emitting device according to an embodiment of the present invention.

FIG. 14B is a schematic cross-sectional view showing a method for manufacturing a light emitting device according to an embodiment of the present invention.

FIG. 14C is a schematic cross-sectional view showing a method for manufacturing a light emitting device according to an embodiment of the present invention.

FIG. 14D is a schematic cross-sectional view showing a method for manufacturing a light emitting device according to an embodiment of the present invention.

FIG. 14E is a schematic cross-sectional view showing a method for manufacturing a light emitting device according to an embodiment of the present invention.

FIG. 14F is a schematic cross-sectional view showing a method for manufacturing a light emitting device according to an embodiment of the present invention.

FIG. 15 is a schematic diagram showing a configuration of a light emitting device formation substrate according to an embodiment of the present invention.

### DESCRIPTION OF EMBODIMENTS

The method for manufacturing a micro LED display device by transferring LED chips has a high manufacturing cost, and it is difficult to manufacture the micro LED display device at low cost. On the other hand, if LEDs can be formed on a large-area substrate such as an amorphous glass substrate, the manufacturing cost can be reduced. However, as described above, since a gallium nitride film is formed on a sapphire substrate at a high temperature, it is difficult to form a gallium nitride film directly on an amorphous glass substrate.

Further, in an LED using gallium nitride, light is emitted not only in the upper surface direction of the LED but also in the side surface direction of the LED. Therefore, if the light emitted in the side direction of the LED can be utilized in a light emitting device, the light emission efficiency in the upper surface direction of the light emitting device can be improved. Moreover, the power consumption of the light emitting device can be reduced.

In view of the above problems, an embodiment of the present invention can provide a light emitting device that includes a semiconductor containing gallium nitride formed on a large-area substrate such as an amorphous glass substrate and has high light extraction efficiency in the upper surface direction. Further, an embodiment of the present invention can provide a light emitting device formation substrate on which a plurality of light emitting devices that include a semiconductor layer containing gallium nitride and have high light extraction efficiency in the upper surface direction are formed.

In the following description, each of the embodiments of the present invention are described with reference to the drawings. Each of the embodiments is merely an example, and a person skilled in the art could easily conceive of the invention by appropriately changing the embodiment while maintaining the gist of the invention, and such changes are naturally included in the scope of the invention. For the sake of clarity of the description, the drawings may be schematically represented with respect to the widths, thicknesses, shapes, and the like of the respective portions in comparison with actual embodiments. However, the illustrated shapes are merely examples and are not intended to limit the interpretation of the present invention.

In the present specification, the expressions “a includes A, B or C”, “a includes any of A, B and C”, and “a includes one selected from the group consisting of A, B and C” do not exclude the case where a includes a plurality of combinations of A to C unless otherwise specified. Further, these expressions do not exclude the case where a includes other elements.

In the present specification, although the phrase “above” or “above direction” or “below” or “below direction” is used for convenience of explanation, in principle, the direction from a substrate toward a structure is referred to as “above” or “above direction” with reference to a substrate in which the structure is formed. Conversely, the direction from the structure to the substrate is referred to as “below” or “below direction”. Therefore, in the expression of a structure over a substrate, one surface of the structure in the direction facing the substrate is the bottom surface of the structure and the other surface is the upper surface of the structure. In addition, the expression of a structure over a substrate only explains the vertical relationship between the substrate and the structure, and another member may be placed between the substrate and the structure. Furthermore, the terms “above” or “above direction” or “below” or “below direction” mean the order of stacked layers in the structure in which a plurality of layers are stacked, and may not be related to the position in which layers overlap in a plan view.

In the specification, terms such as “first”, “second”, or “third” attached to each configuration are convenient terms used to distinguish each configuration, and have no further meaning unless otherwise explained.

In the specification and the drawings, the same reference numerals may be used when multiple configurations are identical or similar in general, and reference numerals with an upper case letter of the alphabet may be used when the multiple configurations are distinguished. Further, reference numerals with a hyphen and a lower case letter may be used when specific portions of one configuration are distinguished.

In the specification, although gallium nitride is described as an example in order to facilitate understanding of the invention, each embodiment is not limited to gallium nitride. In each embodiment, a nitride semiconductor such as gallium nitride or aluminum gallium nitride can be applied.

The following embodiments can be combined with each other as long as there is no technical contradiction.

### First Embodiment

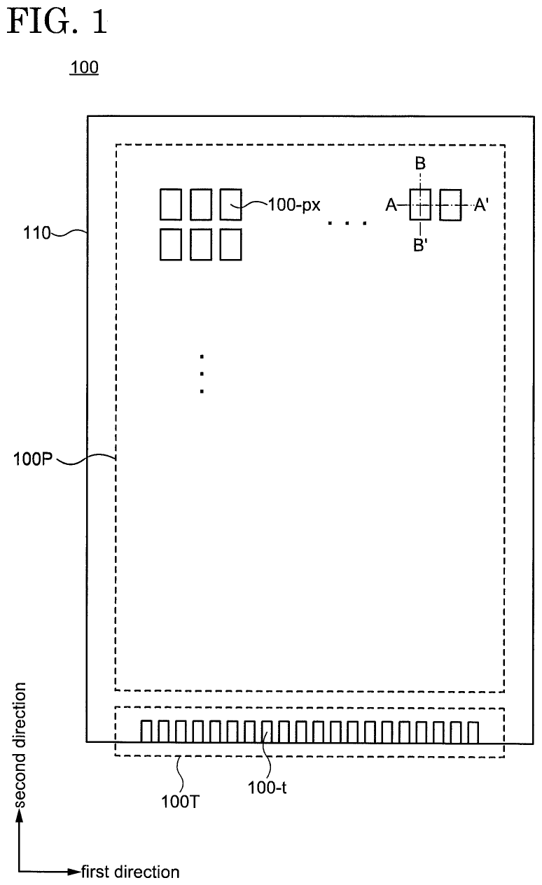

A configuration of a light emitting device 100 according to an embodiment of the present invention is described with reference to FIGS. 1 to 3.

FIG. 1 is a schematic diagram showing a configuration of the light emitting device 100 according to an embodiment of the present invention. In the light emitting device 100, a pixel section 100P and a terminal section 100T are formed on a substrate 110. The pixel portion 100P is formed in the center of the substrate 110, and the terminal portion 100T is formed at an end of the substrate 110. The pixel portion 100P includes a plurality of pixels 100-px arranged in a first direction and a second direction orthogonal to (intersecting) the first direction. Although details are described later, a light emitting diode (LED) is formed in each of the plurality of pixels 100-px. The terminal portion 100T includes a plurality of terminals 100-t. A power supply line is connected to each of the plurality of terminals 100-t, and a voltage can be applied (a current can be supplied) to the LED in the pixel 100-px. In addition, although details are not shown, a transistor can be provided in the pixel 100-px, and the light emission of the LED can be controlled by the transistor.

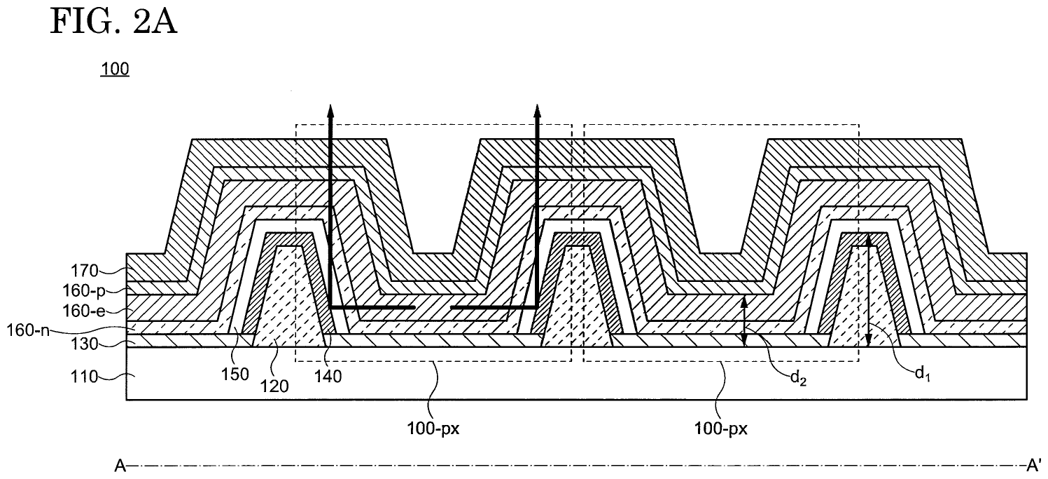

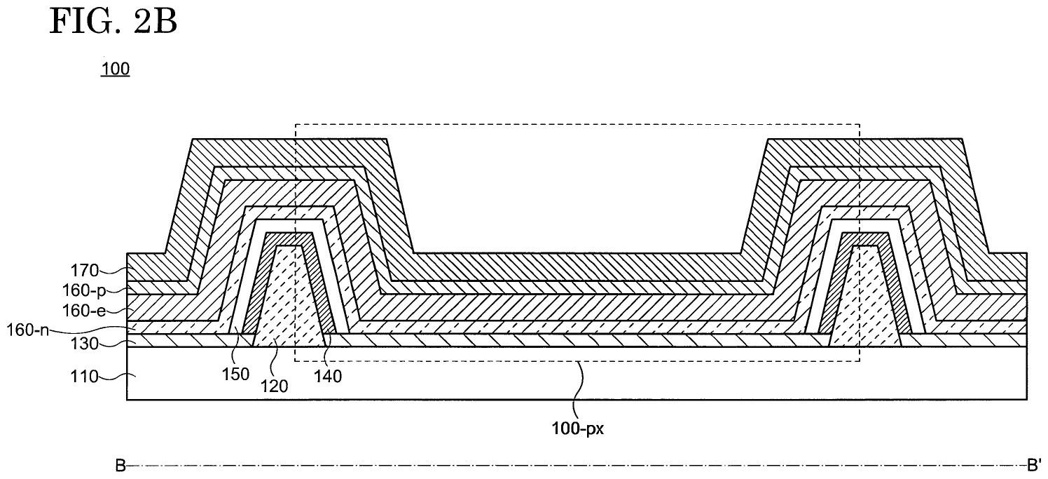

FIGS. 2A and 2B are schematic cross-sectional views showing a configuration of the light emitting device 100 according to an embodiment of the present invention. Specifically, FIG. 2A is a cross-sectional view of the pixel 100-px cut along the first direction (line A-A′) shown in FIG. 1, and FIG. 2B is a cross-sectional view of the pixel 100-px cut along the second direction (line B-B′) shown in FIG. 1. As shown in FIGS. 2A and 2B, the light emitting device 100 includes a substrate 110, a partition wall 120, a conductive alignment layer 130, a reflective layer 140, an insulating layer 150, an n-type semiconductor layer 160-n, a light emitting layer 160-e, a p-type semiconductor layer 160-p, and an electrode layer 170.

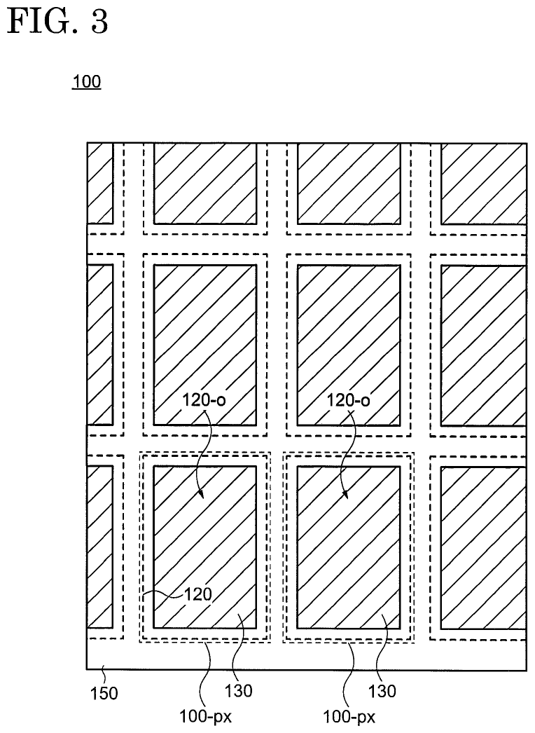

FIG. 3 is a schematic plan view showing a part of a configuration of the light emitting device 100 according to an embodiment of the present invention. Specifically, the partition wall 120, the conductive alignment layer 130, and the insulating layer 150 are shown in FIG. 3.

The partition wall 120 is provided on the substrate 110. In a plan view, the partition wall 120 is provided in a lattice pattern, and each of the pixels 100-px includes an opening portion 120-o through which the substrate 110 is exposed. That is, the pixels 100-px are defined by the partition wall 120 and arranged in a matrix pattern. The partition wall 120 has upper and side surfaces. The side surface of the partition wall 120 is inclined with respect to the substrate 110. The inclination angle of the side surface of the partition wall 120 with respect to the substrate 110 is, for example, greater than or equal to 1 degree and less than or equal to 89 degrees, and preferably greater than or equal to 30 degrees and less than or equal to 60.

The conductive alignment layer 130 is provided on the exposed substrate 110 so as to cover the opening portions 120-o of the partition wall 120. Further, in the plan view, the conductive alignment layer 130 is provided in an island shape in each of the plurality of pixels 100-px.

The reflective layer 140 is provided on the partition wall 120 so as to cover the upper and side surfaces of the partition wall 120. Further, in the plan view, the reflective layer 140 is provided in a lattice shape, similar to the partition wall 120, and includes an opening portion through which the conductive alignment layer 130 is exposed. The reflective layer 140 is in contact with the conductive alignment layer 130.

The insulating layer 150 is provided on the reflective layer 140 so as to cover the reflective layer 140 provided on the upper and side surfaces of the partition wall 120. Further, in the plan view, the insulating layer 150 is provided in a lattice shape, similar to the partition wall 120, and includes an opening portion through which the conductive alignment layer 130 is exposed in each of the plurality of pixels 100-px.

The n-type semiconductor layer 160-n, the light emitting layer 160-e, the p-type semiconductor layer 160-p, and the electrode layer 170 are sequentially provided on the conductive alignment layer 130 and the insulating layer 150. The n-type semiconductor layer 160-n, the light emitting layer 160-e, the p-type semiconductor layer 160-p, and the electrode layer 170 are provided commonly in the plurality of pixels 100-px arranged in a matrix.

Each of the plurality of pixels 100-px includes the conductive alignment layer 130, the n-type semiconductor layer 160-n, the light emitting layer 160-e, the p-type semiconductor layer 160-p, and the electrode layer 170 as an LED. Here, one of the electrodes of the LED is the conductive alignment layer 130, and the other of the electrodes of the LED is the electrode layer 170. Although the conductive alignment layer 130 is provided in an island shape in each of the plurality of pixels 100-px, the conductive alignment layer 130 is electrically connected to the conductive reflective layer 140. That is, the plurality of conductive alignment layers 130 each provided in an island shape are electrically connected to each other via the reflective layer 140. Further, the electrode layer 170 is provided commonly in the plurality of pixels 100-px arranged in a matrix. Therefore, it is not possible to control the light emission of each of the plurality of pixels 100-px in the light emitting device 100.

Next, materials of each component are described.

The substrate 110 is a base material (support substrate) of the light emitting device 100. Although details are described later, each of the n-type semiconductor layer 160-n, the light emitting layer 160-e, and the p-type semiconductor layer 160-p is formed by sputtering in the light emitting device 100. Therefore, it is sufficient that the substrate 110 has a heat resistance of, for example, about 600 degrees, which is a relatively low temperature. For example, an amorphous glass substrate can be used as the substrate 110. Further, a resin substrate such as a polyimide substrate, an acrylic substrate, a siloxane substrate, or a fluororesin substrate can also be used as the substrate 110. Such an amorphous glass substrate or resin substrate is a substrate that can be made large in area.

Although not shown in the figures, the substrate 110 may be provided with a base layer. The base layer can prevent impurities from the substrate 110 or impurities from the outside (e.g., moisture, sodium (Na), etc.) from diffusing. For example, a silicon nitride (SiNₓ) film or the like can be used as the base layer. Further, for example, a laminated film of a silicon oxide (SiOₓ) film and a silicon nitride (SiNₓ) film can also be used as the base layer.

The partition wall 120 defines the plurality of pixels 100-px. For example, an inorganic material such as silicon oxide or silicon nitride, or a laminate of these inorganic materials, can be used for the partition wall 120. Further, an organic material such as acrylic or polyimide can be used for the partition wall 120.

The conductive alignment layer 130 can improve the crystallinity of the gallium nitride (GaN) film deposited on the conductive alignment layer 130 by sputtering. Specifically, the conductive alignment layer 130 can perform control so as to align a c-axis of the gallium nitride film deposited on the conductive alignment layer 130 in the film thickness direction. In other words, the conductive alignment layer 130 can perform control such that the n-type semiconductor layer 160-n has a c-axis orientation. Although GaN having a hexagonal close-packed structure grows in the c-axis direction to minimize surface energy, the crystal growth in the c-axis direction is promoted by forming the gallium nitride film on the conductive alignment layer 130. A conductive material having a hexagonal close-packed structure, a face-centered cubic structure, or a structure equivalent thereto (for example, a wurtzite structure, a corundum structure, or a diamond structure) can be used as the conductive alignment layer 130. Here, the structure equivalent to the hexagonal close-packed structure or the face-centered cubic structure includes a crystal structure in which the c-axis is not 90 degrees with respect to the a-axis and the b-axis. The conductive alignment layer 130 using the conductive material having the hexagonal close-packed structure or the structure equivalent thereto has an orientation in the (0001) direction, that is, the c-axis direction with respect to the substrate 110 (hereinafter, referred to as a (0001) orientation of the hexagonal close-packed structure.). Further, the conductive alignment layer 130 using the conductive material having the face-centered cubic structure or the structure equivalent thereto has an orientation in the (111) direction with respect to the substrate 110 (hereinafter, referred to as a (111) orientation of the face-centered cubic structure.). When the conductive alignment layer 130 has the (0001) orientation of the hexagonal close-packed structure or the (111) orientation of a face-centered cubic structure, the crystal growth of the gallium nitride formed on the conductive alignment layer 130 is promoted. Therefore, the n-type semiconductor layer 160-n has a c-axis orientation with high crystallinity.

As described above, the crystallinity of the gallium nitride film on the conductive alignment layer 130 is affected by the surface condition of the conductive alignment layer 130. Therefore, it is preferable that the conductive alignment layer 130 has a smooth surface with little unevenness. For example, the arithmetic mean roughness (Ra) of the surface of the conductive alignment layer 130 is preferably less than 2.3 nm. Further, the root mean square roughness (Rq) of the surface of the alignment layer 130 is preferably less than 2.9 nm. When the surface roughness of the conductive alignment layer 130 is under the above conditions, the n-type semiconductor layer 160-n has the c-axis orientation with higher crystallinity. In addition, the thickness of the conductive alignment layer 130 is preferably greater than or equal to 50 nm.

The conductive alignment layer 130 not only functions as an n-type electrode of the LED but also functions to reflect the light emitted from the lower surface of the light emitting layer 160-e toward the upper surface. Therefore, the conductive alignment layer 130 has both conductivity and reflectivity. For example, titanium (Ti), titanium nitride (TiNₓ), titanium oxide (TiOₓ), graphene, zinc oxide (ZnO), magnesium diboride (MgB₂), aluminum (Al), silver (Ag), calcium (Ca), nickel (Ni), copper (Cu), strontium (Sr), rhodium (Rh), palladium (Pd), cerium (Ce), ytterbium (Yb), iridium (Ir), platinum (Pt), gold (Au), lead (Pb), actinium (Ac), thorium (Th), BiLaTiO, SrFeO, BiFeO, BaFeO, ZnFeO, or PMnN-PZT can be used for the conductive alignment layer 130. In particular, it is preferable to use titanium for the conductive alignment layer 130.

The reflective layer 140 reflects the light emitted from the side surface of the light emitting layer 160-e toward the upper surface. For example, silver (Ag), titanium (Ti), molybdenum (Mo), tungsten (W), aluminum (Al), or an alloy thereof can be used for the reflective layer 140. The reflective layer 140 may also be conductive.

The insulating layer 150 separates (electrically insulates) the reflective layer 140 and the n-type semiconductor layer 160-n. For example, an inorganic material such as silicon oxide or silicon nitride, or a laminate of these inorganic materials can be used for the insulating layer 150.

The n-type semiconductor layer 160-n transports electrons and injects the electrons into the light emitting layer 160-e. For example, a gallium nitride film doped with silicon (Si) can be used as the n-type semiconductor layer 160-n.

The light emitting layer 160-e recombines the injected electrons and holes to emit light. The light emitting layer 160-e may have a multiple quantum well structure. For example, a laminated film in which indium gallium nitride (InGaN) films and gallium nitride films are alternately laminated can be used as the light emitting layer 160-e.

The p-type semiconductor layer 160-p transports holes and injects the holes into the light emitting layer 160-e. For example, a gallium nitride film doped with magnesium (Mg) can be used as the p-type semiconductor layer 160-p.

The electrode layer 170 functions as a p-type electrode of the LED. For example, a metal material such as palladium (Pd) or gold (Au) can be used for the electrode layer 170.

In the light emitting device 100, the electrode layer 170 may function as an n-type electrode of the LED. In this case, the light emitting device 100 has a structure in which the n-type semiconductor layer 160-n is in contact with the electrode layer 170. That is, the p-type semiconductor layer 160-p, the light emitting layer 160-e, and the n-type semiconductor layer 160-n are sequentially provided on the conductive alignment layer 130. In this case, a metal material such as silver (Ag) or indium (In), or a transparent conductive oxide such as indium tin oxide (ITO), indium zinc oxide (IZO), or zinc oxide (ZnO) can be used for the electrode layer 170, for example.

In the light emitting device 100, light emitted from the light emitting layer 160-e is extracted through the electrode layer 170. Therefore, the electrode layer 170 has light-transmitting or semi-light-transmitting properties. When a metal material is used for the electrode layer 170, the electrode layer 170 having semi-light-transmitting properties is formed by reducing the film thickness of the metal material. In addition, the electrode layer 170 may have a laminate of a metal material and a transparent conductive oxide.

Although not shown in the figures, a protective film can be provided to cover the LED as necessary. A silicon nitride film can be used as the protective film. Further, for example, a laminated film of a silicon oxide film and a silicon nitride film can be used as the protective film.

In the light emitting device 100, the n-type semiconductor layer 160-n is in contact with the conductive alignment layer 130 in a region where the partition wall 120 is not provided (or a region not overlapping the partition wall 120, hereinafter referred to as a “non-partition-formed region”). Therefore, the crystallinity of the n-type semiconductor layer 160-n is improved in the non-partition-formed region. Further, the crystallinity of not only the n-type semiconductor layer 160-n but also the light emitting layer 160-e and the p-type semiconductor layer 160-p is improved in the non-partition-formed region. Therefore, in the light emitting device 100, the light emission intensity from the light emitting layer 160-e is increased in the non-partition-formed region.

Further, in the light emitting device 100, the distance d₁ from the upper surface of the substrate 110 to the upper surface of the reflective layer 140 in a region where the partition wall 120 is provided (or a region overlapping the partition wall 120, hereinafter referred to as the “partition-formed region”) is greater than the distance d₂ from the upper surface of the substrate 110 to the upper surface of the light emitting layer 160-e in the non-partition-formed region. Therefore, the light emitted from the side surface of the light emitting layer 160-e is reflected toward the upper surface of the light emitting device 100 by the reflective layer 140 provided on the side surface of the partition wall 120. Accordingly, in the light emitting device 100, the light extraction efficiency in the upper surface direction is increased, and the light emission efficiency in the upper surface direction can be improved.

### First Modification of First Embodiment

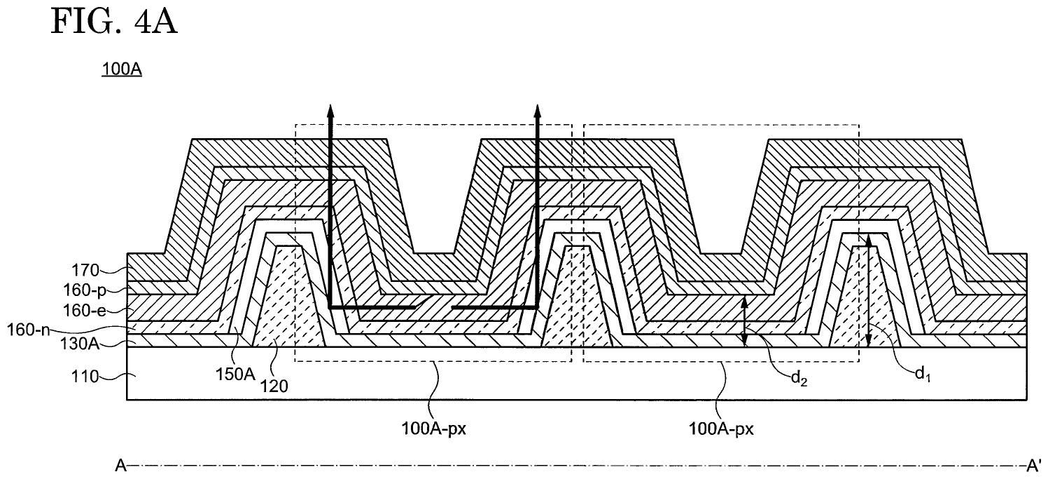

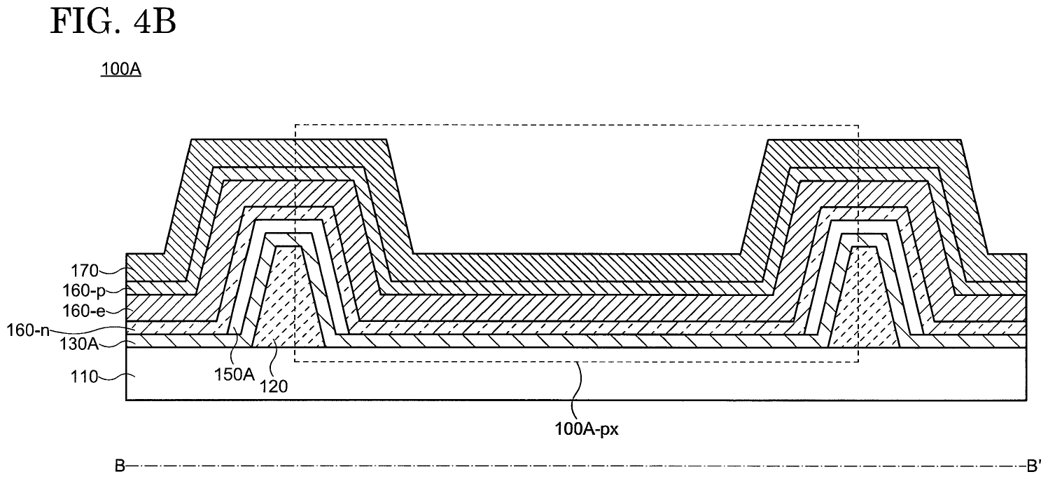

A light emitting device 100A, which is one of the modifications of the light emitting device 100 is described with reference to FIGS. 4A and 4B. In addition, when a configuration of the light emitting device 100A is similar to the configuration of the light emitting device 100, the description thereof may be omitted.

FIGS. 4A and 4B are cross-sectional views showing a configuration of the light emitting device 100A according to an embodiment of the present invention. Specifically, FIG. 4A is a cross-sectional view of a pixel 100A-px cut along the first direction, and FIG. 4B is a cross-sectional view of the pixel 100A-px cut along the second direction. As shown in FIGS. 4A and 4B, the light emitting device 100A includes the substrate 110, the partition wall 120, a conductive alignment layer 130A, an insulating layer 150A, the n-type semiconductor layer 160-n, the light emitting layer 160-e, the p-type semiconductor layer 160-p, and the electrode layer 170.

The conductive alignment layer 130A covers the partition wall 120 and is provided on the substrate 110 and the partition wall 120. Further, in a plan view, the conductive alignment layer 130A is provided commonly in the plurality of pixels 100-px arranged in a matrix.

In the light emitting device 100A, although a reflective layer is not provided, the conductive alignment layer 130A can function as a reflective layer. When the conductive alignment layer 130 and the reflective layer 140 are formed using the same material in the light emitting device 100, the light emitting device 100 has the same configuration as the light emitting device 100A. In other words, the conductive alignment layer 130A of the light emitting device 100A has a configuration in which the reflective layer in the light emitting device 100 is the same layer as the conductive alignment layer and is made of the same material.

The insulating layer 150A is provided on the conductive alignment layer 130A so as to cover the conductive alignment layer 130A provided on the upper and side surfaces of the partition wall 120. Further, in a plan view, the insulating layer 150A is provided in a lattice shape, similar to the partition wall 120, and includes an opening portion through which the conductive alignment layer 130A is exposed.

Each of the pixels 100A-px includes the conductive alignment layer 130A, the n-type semiconductor layer 160-n, the light emitting layer 160-e, the p-type semiconductor layer 160-p, and the electrode layer 170 as an LED. Here, one of the electrodes of the LED is the conductive alignment layer 130A, and the other of the electrodes of the LED is the electrode layer 170. The conductive alignment layer 130A and the electrode layer 170 are provided commonly in the plurality of pixels 100A-px arranged in a matrix. Therefore, it is not possible to control the light emission of each of the plurality of pixels 100-px in the light emitting device 100A.

In the light emitting device 100A, the n-type semiconductor layer 160-n is in contact with the conductive alignment layer 130A in the non-partition-formed region. Therefore, the crystallinity of the n-type semiconductor layer 160-n is improved in the non-partition-formed region. Further, the crystallinity of not only the n-type semiconductor layer 160-n but also the light emitting layer 160-e and the p-type semiconductor layer 160-p is improved in the non-partition-formed region. Therefore, in the light emitting device 100A, the light emission intensity from the light emitting layer 160-e is increased in the non-partition-formed region.

Further, in the light emitting device 100A, the distance d₁ from the upper surface of the substrate 110 to the upper surface of the conductive alignment layer 130A in the partition-formed region is greater than the distance d₂ from the upper surface of the substrate 110 to the upper surface of the light emitting layer 160-e in the partition-non-formed region. Therefore, the light emitted from the side surface of the light emitting layer 160-e is reflected toward the upper surface of the light emitting device 100A by the conductive alignment layer 130A provided on the side surface of the partition wall 120. Accordingly, in the light emitting device 100A, the light extraction efficiency in the upper surface direction is increased, and the light emission efficiency in the upper surface direction can be improved.

### Modification 2 of First Embodiment

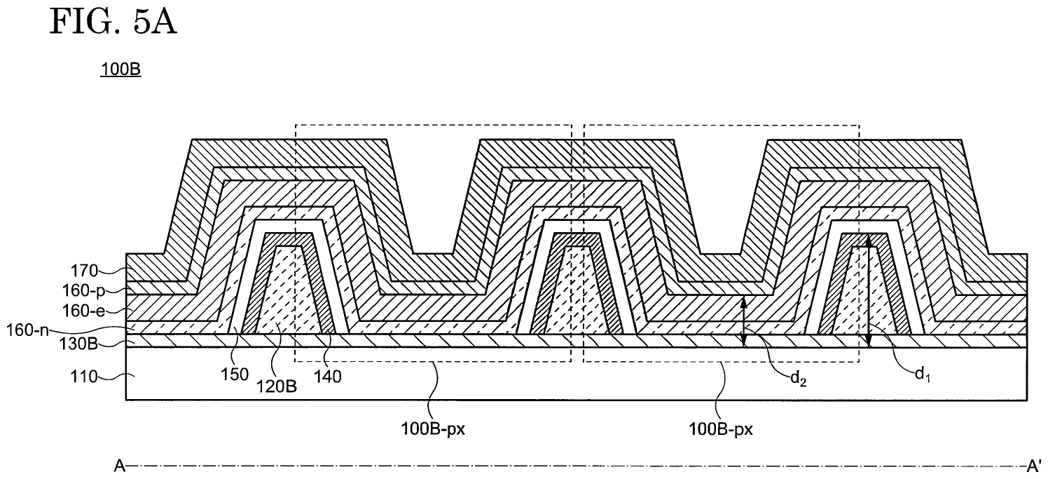

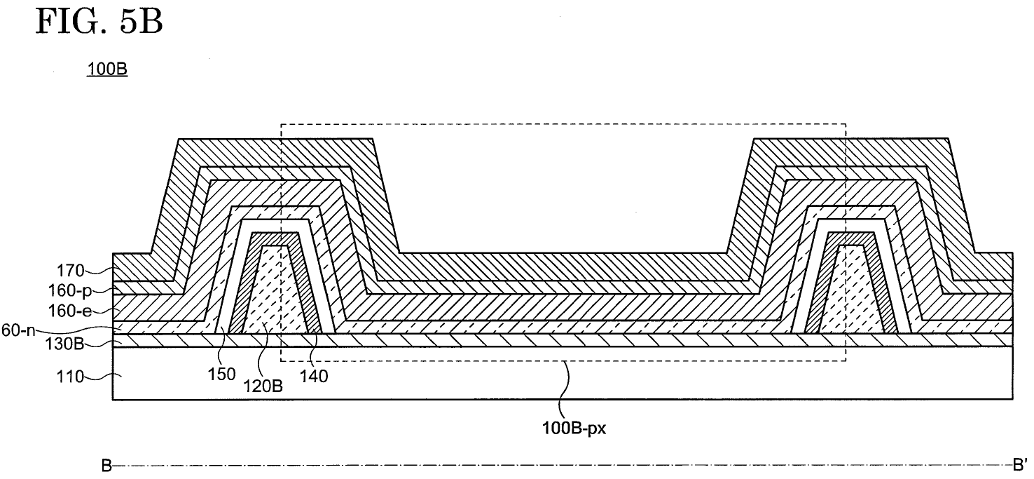

A light emitting device 100B, which is one of the modifications of the light emitting device 100 is described with reference to FIGS. 5A and 5B. In addition, when a configuration of the light emitting device 100B is similar to the configuration of the light emitting device 100 or the light emitting device 100A, the description thereof may be omitted.

FIGS. 5A and 5B are cross-sectional views showing a configuration of the light emitting device 100B according to an embodiment of the present invention. Specifically, FIG. 5A is a cross-sectional view of a pixel 100B-px cut along the first direction, and FIG. 5B is a cross-sectional view of the pixel 100B-px cut along a second direction. As shown in FIGS. 5A and 5B, the light emitting device 100B includes the substrate 110, a conductive alignment layer 130B, a partition wall 120B, the reflective layer 140, the insulating layer 150, the n-type semiconductor layer 160-n, the light emitting layer 160-e, the p-type semiconductor layer 160-p, and the electrode layer 170.

The conductive alignment layer 130B is provided on the substrate 110. Further, the conductive alignment layer 130B is provided commonly in the plurality of pixels 100B-px arranged in a matrix.

The partition wall 120B is provided on the conductive alignment layer 130B. In a plan view, the partition wall 120B is provided in a lattice shape and includes an opening portion through which the conductive alignment layer 130B is exposed in each of the plurality of pixels 100B-px. In other words, the plurality of pixels 100B-px are defined by the partition wall and arranged in a matrix. Each of the pixels 100B-px includes the conductive alignment layer 130B, the n-type semiconductor layer 160-n, the light emitting layer 160-e, the p-type semiconductor layer 160-p, and the electrode layer 170 as an LED. Here, one of the electrodes of the LED is the conductive alignment layer 130B, and the other of the electrodes of the LED is the electrode layer 170. The conductive alignment layer 130B and the electrode layer 170 are provided commonly in the plurality of pixels 100B-px arranged in a matrix. Therefore, it is not possible to control the light emission of each of the plurality of pixels 100-px in the light emitting device 100B.

In the light emitting device 100B, the n-type semiconductor layer 160-n is in contact with the conductive alignment layer 130B in the non-partition-formed region. Therefore, the crystallinity of the n-type semiconductor layer 160-n is improved in the non-partition-formed region. Further, the crystallinity of not only the n-type semiconductor layer 160-n but also the light emitting layer 160-e and the p-type semiconductor layer 160-p is improved in the non-partition-formed region. Therefore, in the light emitting device 100B, the light emission intensity from the side surface of the light emitting layer 160-e is increased in the non-partition-formed region.

Further, in the light emitting device 100B, the distance d₁ from the upper surface of the substrate 110 to the upper surface of the reflective layer 140 in the partition-formed region is greater than the distance d₂ from the upper surface of the substrate 110 to the upper surface of the light emitting layer 160-e in the non-partition-formed region. Therefore, the light emitted from the light emitting layer 160-e is reflected toward the upper surface of the light emitting device 100B by the reflective layer 140 provided on the side surface of the partition wall 120. Accordingly, in the light emitting device 100B, the light extraction efficiency in the upper surface direction is increased, and the light emission efficiency in the upper surface direction can be improved.

### Modification 3 of First Embodiment

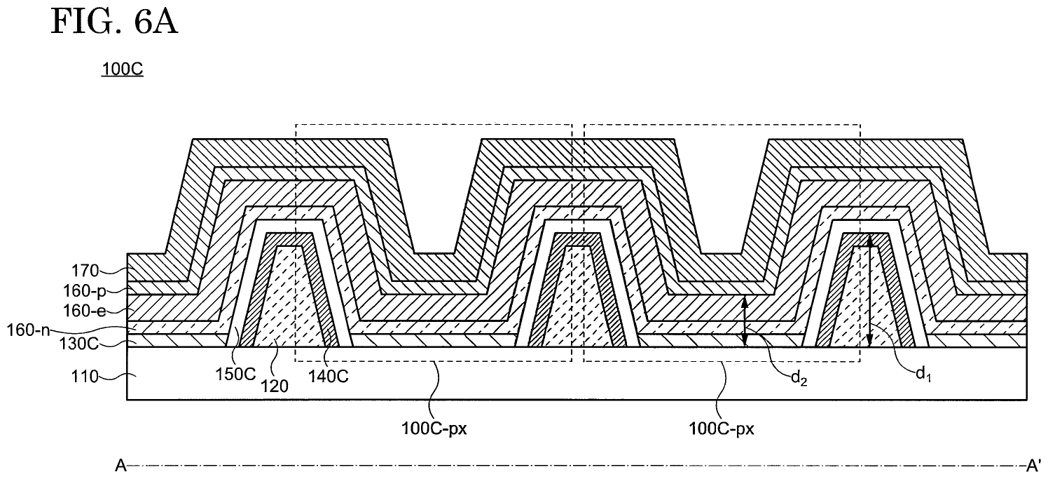

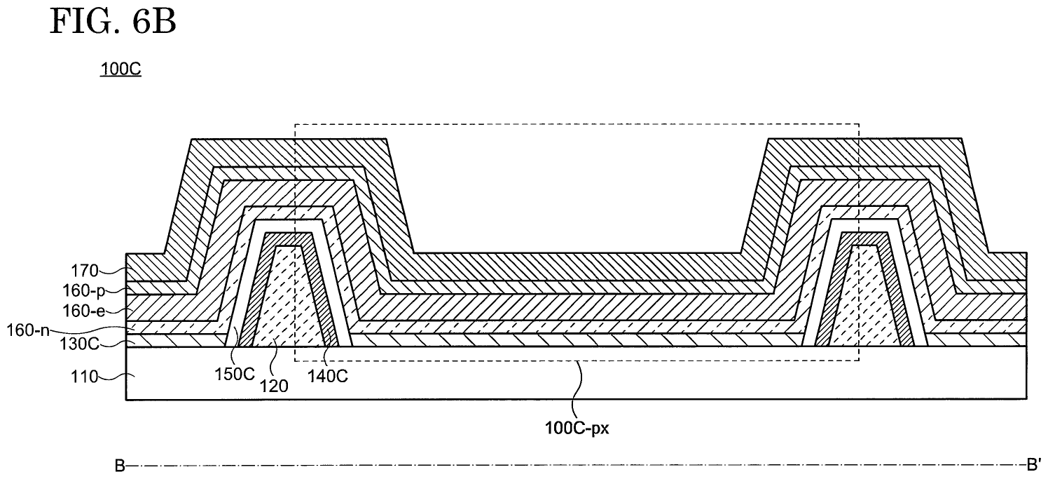

A light emitting device 1000, which is one of the modifications of the light emitting device 100 is described with reference to FIGS. 6A and 6B. In addition, when a configuration of the light emitting device 1000 is similar to the configuration of the light emitting device 100, the description thereof may be omitted.

FIGS. 6A and 6B are cross-sectional views showing a configuration of the light emitting device 1000 according to an embodiment of the present invention. Specifically, FIG. 6A is a cross-sectional view of a pixel 1000-px cut along the first direction, and FIG. 6B is a cross-sectional view of the pixel 1000-px cut along the second direction. As shown in FIG. 6A and FIG. 6B, the light emitting device 1000 includes the substrate 110, the partition wall 120, a reflective layer 140C, an insulating layer 150C, a conductive alignment layer 130C, the n-type semiconductor layer 160-n, the light emitting layer 160-e, the p-type semiconductor layer 160-p, and the electrode layer 170.

The reflective layer 140C is provided on the substrate 110 and the partition wall 120 so as to cover the upper and side surfaces of the partition wall 120. Further, in a plan view, the reflective layer 140C is provided in a lattice shape, similar to the partition wall 120, and includes an opening portion through which the substrate 110 is exposed in each of the plurality of pixels 1000-px.

The insulating layer 150C is provided on the substrate 110 and the reflective layer 140C so as to cover the reflective layer 140C. Further, in the plan view, the insulating layer 150C is provided in a lattice shape and includes an opening portion through which the substrate 110 is exposed in each of the multiple pixels 1000-px.

The conductive alignment layer 130C is provided on the substrate 110 so as to cover the opening portion of the insulating layer 150C. Further, in the plan view, the conductive alignment layer 130C is provided in an island shape in each of the plurality of pixels 1000-px.

Each of the pixels 1000-px includes the conductive alignment layer 130C, the n-type semiconductor layer 160-n, the light emitting layer 160-e, the p-type semiconductor layer 160-p, and the electrode layer 170 as an LED. Here, one of the electrodes of the LED is the conductive alignment layer 130C, and the other of the electrodes of the LED is the electrode layer 170. The electrode layer 170 is provided commonly in a plurality of pixels 1000-px arranged in a matrix. The conductive alignment layer 130C is formed in an island shape in the pixel 1000-px. In the light emitting device 1000, a transistor or the like that controls the LED is provided on the substrate 110, and the conductive alignment layer 130C and the transistor are electrically connected. This makes it possible to control the light emission of each of the pixels 1000-px. That is, in the light emitting device 1000, the light emission of the pixel 1000-px can be controlled by active driving.

In the light emitting device 1000, the n-type semiconductor layer 160-n is in contact with the conductive alignment layer 130C in the non-partition-formed region. Therefore, the crystallinity of the n-type semiconductor layer 160-n is improved in the non-partition-formed region. Further, the crystallinity of not only the n-type semiconductor layer 160-n but also the light emitting layer 160-e and the p-type semiconductor layer 160-p is improved in the non-partition-formed region. Therefore, in the light emitting device 1000, the light emission intensity from the light emitting layer 160-e is increased in the non-partition-formed region.

Further, in the light emitting device 1000, the distance d₁ from the upper surface of the substrate 110 to the upper surface of the reflective layer 140C in the partition-formed region is greater than the distance d₂ from the upper surface of the substrate 110 to the upper surface of the light emitting layer 160-e in the non-partition-formed region. Therefore, the light emitted from the side surface of the light emitting layer 160-e is reflected toward the upper surface of the light emitting device 1000 by the reflective layer 140C provided on the side surface of the partition wall 120. Accordingly, in the light emitting device 1000, the light extraction efficiency in the upper surface direction is increased, and the light emission efficiency in the upper surface direction can be improved.

### Fourth Modification of the First Embodiment

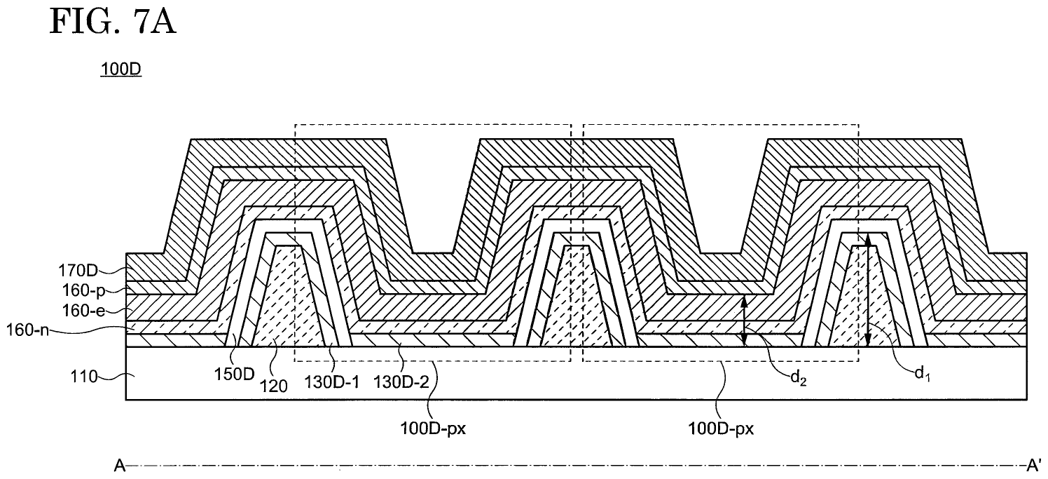

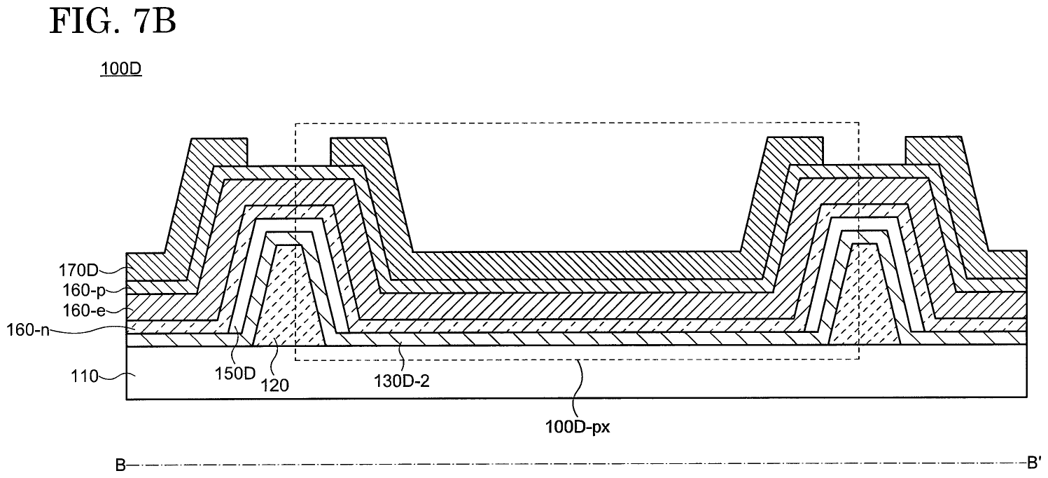

Alight emitting device 100D, which is one of the modifications of the light emitting device 100 is described with reference to FIGS. 7A and 7B. In addition, when a configuration of the light emitting device 100D is similar to the configuration of the light emitting device 100, the description thereof may be omitted.

FIGS. 7A and 7B are cross-sectional views showing a configuration of the light emitting device 100D according to an embodiment of the present invention. Specifically, FIG. 7A is a cross-sectional view of a pixel 100D-px cut along the first direction, and FIG. 7B is a cross-sectional view of the pixel 100D-px cut along the second direction. As shown in FIGS. 7A and 7B, the light emitting device 100D includes the substrate 110, the partition wall 120, a first conductive alignment layer 130D-1, a second conductive alignment layer 130D-2, an insulating layer 150D, the n-type semiconductor layer 160-n, the light emitting layer 160-e, the p-type semiconductor layer 160-p, and an electrode layer 170D.

The first conductive alignment layer 130D-1 is provided on the partition wall 120 so as to cover the upper and side surfaces of the partition wall 120. Further, in a plan view, the first conductive alignment layer 130D-1 extends in the second direction and is provided commonly in a plurality of pixels 100D-px arranged in the second direction. The first conductive alignment layer 130D-1 can function as a reflective layer.

The insulating layer 150D is provided on the first conductive alignment layer 130D-1 so as to cover the first conductive alignment layer 130D-1. Further, in the plan view, the insulating layer 150D is provided in a lattice shape and includes an opening portion through which the substrate 110 is exposed in each of the plurality of pixels 100D-px.

The second conductive alignment layer 130D-2 is provided on the substrate 110 so as to cover the opening portion of the insulating layer 150. Further, in the plan view, the second conductive alignment layer 130D-2 extends in the second direction and is provided commonly in the plurality of pixels 100D-px arranged in the second direction. The second conductive alignment layer 130D-2 can function as an electrode of the LED. Furthermore, a part of the second conductive alignment layer 130D-2 can function as a reflective layer.

The first conductive alignment layer 130D-1 and the second conductive alignment layer 130D-2 are separated by the insulating layer 150D. In addition, the first conductive alignment layer 130D-1 and the second conductive alignment layer 130D-2 are the same layer and are formed of the same material.

The electrode layer 170D is provided on the p-type semiconductor layer 160-p. Further, in the plan view, the electrode layer 170D extends in the first direction and is provided commonly in a plurality of pixels 100D-px arranged in the first direction.

Each of the pixels 100D-px includes the second conductive alignment layer 130D-2, the n-type semiconductor layer 160-n, the light emitting layer 160-e, the p-type semiconductor layer 160-p, and the electrode layer 170D as an LED. Here, one of the electrodes of the LED is the second conductive alignment layer 130D-2, and the other of the electrodes of the LED is the electrode layer 170D. The electrode layer 170D extends in the first direction, and the second conductive alignment layer 130D-2 extends in the second direction. Therefore, it is possible to control the light emission of the pixel 100D-px at the position where the electrode layer 170D and the second conductive alignment layer 130D-2 intersect each other in the light emitting device 100D. That is, it is possible to control the light emission of the pixel 100D-px by passive driving in the light emitting device 100D.

In the light emitting device 100D, the n-type semiconductor layer 160-n is in contact with the second conductive alignment layer 130D-2 in the non-partition region. Therefore, the crystallinity of the n-type semiconductor layer 160-n is improved in the non-partition-formed region. Further, the crystallinity of not only the n-type semiconductor layer 160-n but also the light emitting layer 160-e and the p-type semiconductor layer 160-p is improved in the non-partition-formed region. Therefore, in the light emitting device 100D, the light emission intensity from the light emitting layer 160-e is increased in the non-partition-formed region.

Further, in the light emitting device 100D, the distance d₁ from the upper surface of the substrate 110 to the upper surface of the first conductive alignment layer 130D-1 in the partition-formed region is greater than the distance d₂ from the upper surface of the substrate 110 to the upper surface of the light emitting layer 160-e in the non-partition-formed region. Therefore, the light emitted from the side surface of the light emitting layer 160-e is reflected toward the upper surface of the light emitting device 100D by the first conductive alignment layer 130D-1 provided on the side surface of the partition wall 120. Accordingly, in the light emitting device 100D, the light extraction efficiency in the upper surface direction is increased, and the light emission efficiency in the upper surface direction can be improved.

### Fifth Modification of First Embodiment

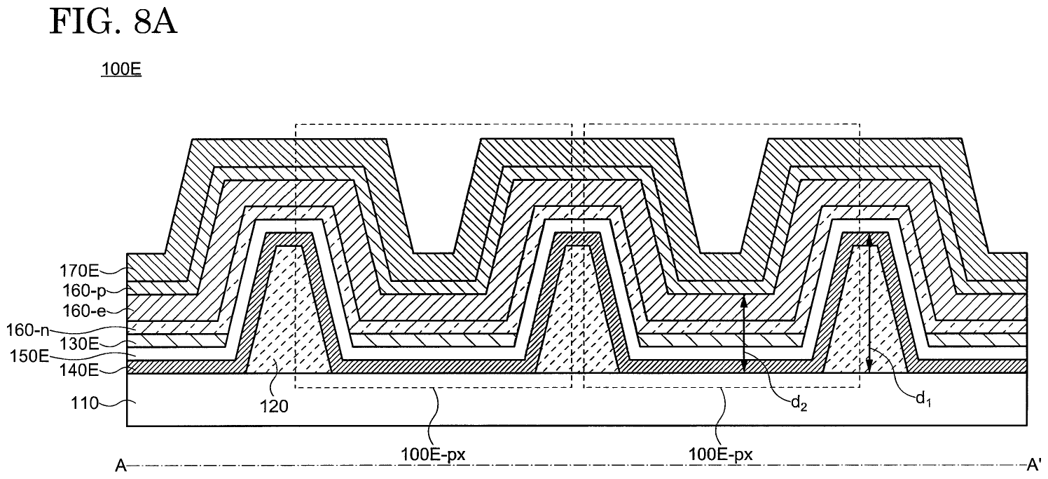

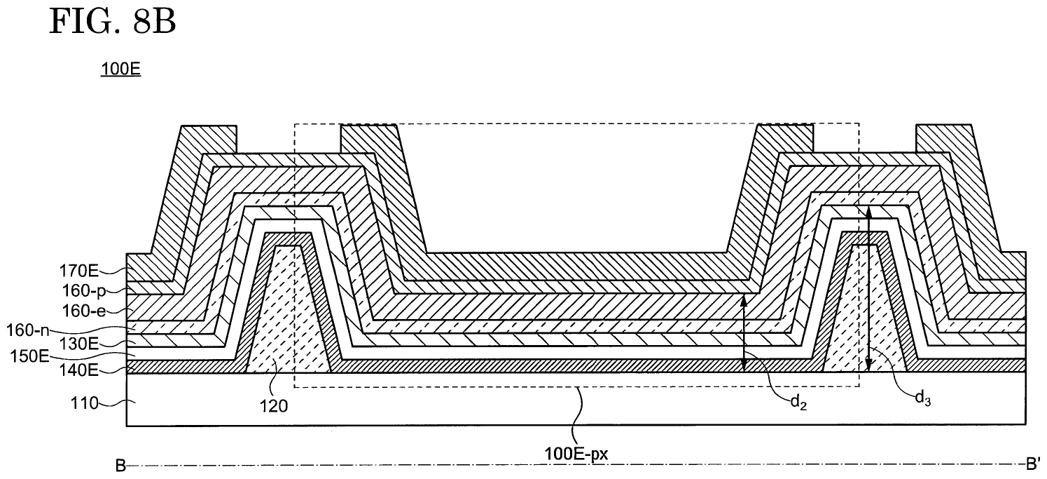

A light emitting device 100E, which is one of the modifications of the light emitting device 100 is described with reference to FIGS. 8A and 8B. In addition, when a configuration of the light emitting device 100E is similar to the configuration of the light emitting device 100, the description thereof may be omitted.

FIGS. 8A and 8B are cross-sectional views showing a configuration of the light emitting device 100E according to an embodiment of the present invention. Specifically, FIG. 8A is a cross-sectional view of a pixel 100E-px cut along the first direction, and FIG. 8B is a cross-sectional view of the pixel 100E-px cut along the second direction. As shown in FIG. 8A and FIG. 8B, the light emitting device 100E includes the substrate 110, the partition wall 120, a reflective layer 140E, an insulating layer 150E, a conductive alignment layer 130E, the n-type semiconductor layer 160-n, the light emitting layer 160-e, the p-type semiconductor layer 160-p, and the electrode layer 170.

The reflective layer 140E is provided on the substrate 110 and the partition wall 120 so as to cover the partition wall 120. Further, the reflective layer 140E is provided commonly in common to the plurality of pixels 100E-px arranged in a matrix.

The insulating layer 150E is provided on the reflective layer 140 so as to cover the reflective layer 140. The insulating layer 150E is provided commonly in the plurality of pixels 100E-px arranged in a matrix.

The conductive alignment layer 130E is provided on the insulating layer 150E. Further, in a plan view, the conductive alignment layer 130E extends in the second direction and is provided commonly in a plurality of pixels 100E-px arranged in the second direction. Furthermore, the conductive alignment layer 130E is provided so as to cover the upper and side surfaces of the partition wall 120 in the second direction.

The electrode layer 170E is provided on the p-type semiconductor layer 160-p. Further, in the plan view, the electrode layer 170E extends in the first direction and is provided commonly in a plurality of pixels 100E-px arranged in the first direction.

Each of the pixels 100E-px includes the conductive alignment layer 130E, the n-type semiconductor layer 160-n, the light emitting layer 160-e, the p-type semiconductor layer 160-p, and the electrode layer 170E as an LED. Here, one of the electrodes of the LED is the conductive alignment layer 130E, and the other of the electrodes of the LED is the electrode layer 170E. The electrode layer 170E extends in the first direction, and the conductive alignment layer 130E extends in the second direction. Therefore, it is possible to control the light emission of the pixel 100E-px at the position where the electrode layer 170E and the conductive alignment layer 130E intersect each other in the light emitting device 100E. That is, it is possible to control the light emission of the pixel 100E-px by passive driving in the light emitting device 100E.

In the light emitting device 100E, the n-type semiconductor layer 160-n is in contact with the conductive alignment layer 130E in the non-partition-formed region. Therefore, the crystallinity of the n-type semiconductor layer 160-n is improved in the non-partition-formed region. Further, the crystallinity of not only the n-type semiconductor layer 160-n but also the light emitting layer 160-e and the p-type semiconductor layer 160-p is improved in the non-partition-formed region. Therefore, in the light emitting device 100D, the light emission intensity from the light emitting layer 160-e is increased in the non-partition-formed region.

Further, in the light emitting device 100E, the distance d₁ from the upper surface of the substrate 110 to the upper surface of the reflective layer 140E in the partition-formed region is greater than the distance d₂ from the upper surface of the substrate 110 to the upper surface of the light emitting layer 160-e in the partition-forming region. Furthermore, the distance d₃ from the upper surface of the substrate 110 to the upper surface of the conductive alignment layer 130E in the partition-formed region is greater than the distance d₂ from the upper surface of the substrate 110 to the upper surface of the light emitting layer 160-e in the non-partition-formed region. Therefore, the light emitted from the side surface of the light emitting layer 160-e is reflected toward the upper surface of the light emitting device 100D by the reflective layer 140E provided on the side surface of the partition wall 120 in the first direction and by the conductive alignment layer 130E provided on the side surface of the partition wall 120 in the second direction. Accordingly, in the light emitting device 100E, the light extraction efficiency in the upper surface direction is increased, and the light emission efficiency in the upper surface direction can be improved.

### Second Embodiment

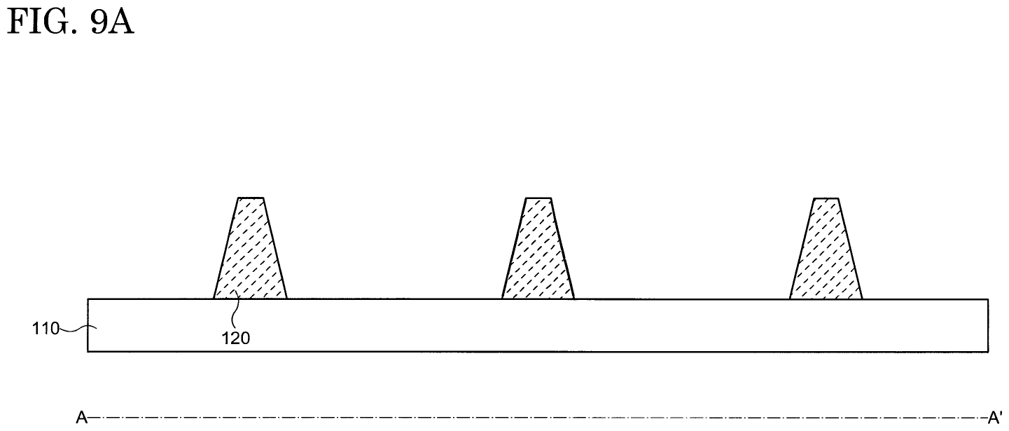

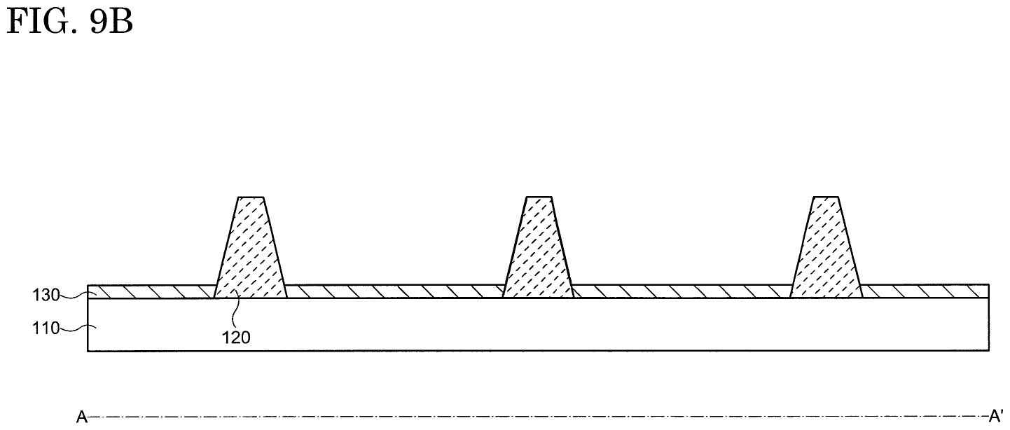

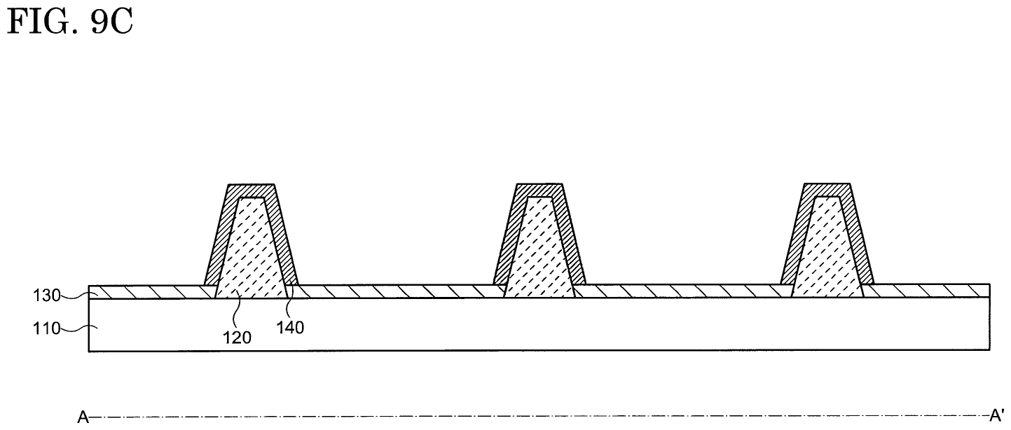

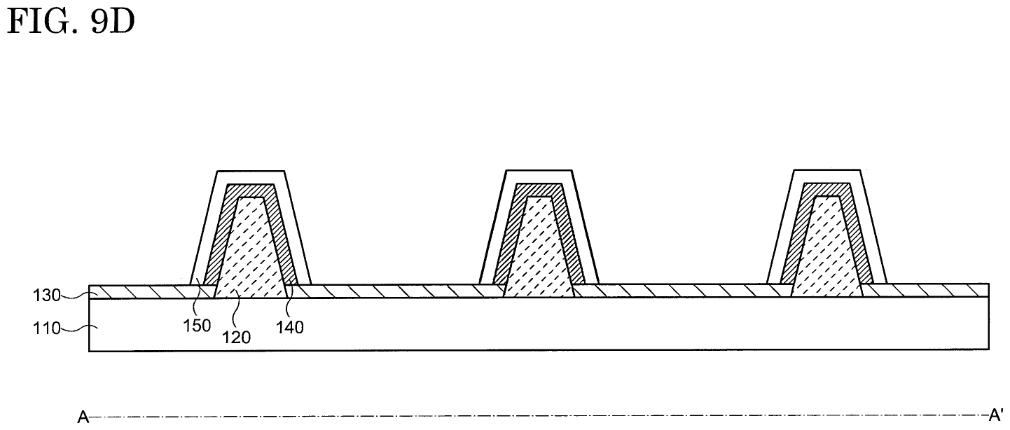

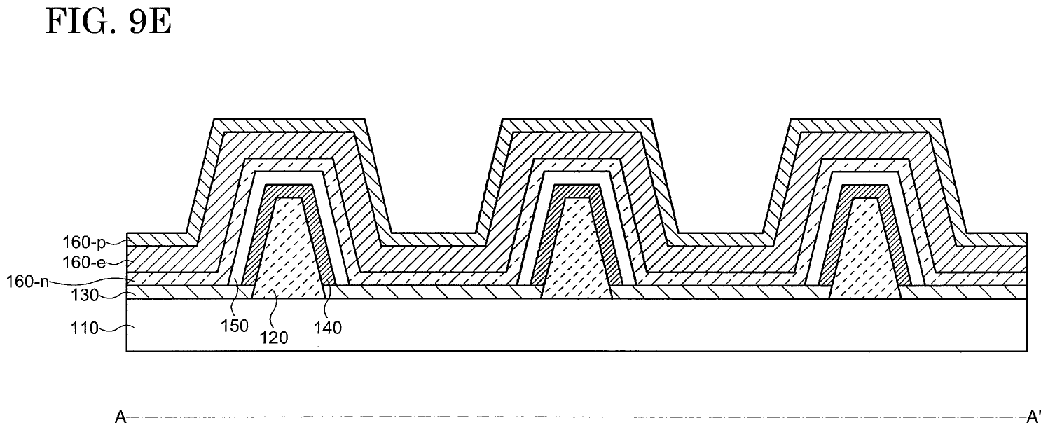

A method for manufacturing the light emitting device 100 according to an embodiment of the present invention is described with reference to FIGS. 9A to 9E. FIGS. 9A to 9E are schematic cross-sectional views showing a method for manufacturing the light emitting device 100 according to an embodiment of the present invention.

First, as shown in FIG. 9A, the partition wall 120 including an opening portion where the substrate 110 is exposed is formed on the substrate 110. The partition wall 120 is formed by depositing an inorganic or organic material and patterning the inorganic or organic material using photolithography. In addition, the patterning may be performed using a half-tone mask or a gray-tone mask in order to form the partition wall 120 having an inclined side surface.

Next, as shown in FIG. 9B, the conductive alignment layer 130 is formed in the opening portion through which the substrate 110 is exposed. The conductive alignment layer 130 can be formed around the partition wall 120 by depositing a film using any method (apparatus) such as sputtering or CVD, and patterning the film.

Next, as shown in FIG. 9C, the reflective layer 140 is formed to cover the upper and side surfaces of the partition wall 120 and to include an opening portion through which the conductive alignment layer 130 is exposed. The reflective layer 140 can be formed by deposition using any method (apparatus) such as sputtering or CVD.

Next, as shown in FIG. 9D, the insulating layer 150 is formed to cover the reflective layer 140 formed on the upper and side surfaces of the partition wall 220 and to include an opening portion exposing the conductive alignment layer 130. The insulating layer 150 is formed by depositing an inorganic material and patterning the inorganic material using photolithography.

Next, as shown in FIG. 9E, the n-type semiconductor layer 160-n, the light emitting layer 160-e, and the p-type semiconductor layer 160-p are sequentially formed so as to cover the opening portion through which the conductive alignment layer 130 is exposed. Each of the n-type semiconductor layer 160-n, the light emitting layer 160-e, and the p-type semiconductor layer 160-p can be formed by deposition using sputtering. In addition, the region overlapping the opening portion of the insulating layer 150 in the n-type semiconductor layer 160-n, the light emitting layer 160-e, and the p-type semiconductor layer 160-p has high crystallinity because it is formed on the conductive alignment layer 130.

Here, deposition of a gallium nitride film using sputtering is described as an example.

The substrate 110 on which the conductive alignment layer 130 is formed is placed to face a gallium nitride target in a vacuum chamber. It is preferable that the composition ratio of gallium nitride in the gallium nitride target is preferably greater than or equal to 0.7 and less or equal to 2 of gallium to nitrogen. Further, nitrogen can also be supplied to the vacuum chamber as a gas other than the sputtering gas (such as argon or krypton). In that case, it is preferable that the composition ratio of gallium nitride in the gallium nitride target is more gallium than nitrogen. For example, nitrogen can be supplied using a nitrogen radical source. The sputtering power supply source may be either a DC power supply source, an RF power supply source, or a pulsed DC power supply source.

The substrate 110 in the vacuum chamber may be heated. For example, the substrate 110 can be heated at a temperature higher than or equal to 400 degrees and lower than 600 degrees. This substrate temperature can be applied even to an amorphous glass substrate with low heat resistance. Further, this substrate temperature is lower than the film formation temperature in MOCVD or HVPE.

After the vacuum chamber is sufficiently evacuated, the sputtering gas is supplied to the vacuum chamber. Further, a voltage is applied between the substrate 100 and the gallium nitride target at a predetermined pressure to generate plasma and the gallium nitride film is deposited.

Although the method for forming the gallium nitride film by sputtering is described above, the configuration or conditions of sputtering can be changed as appropriate. Further, an n-type nitride semiconductor film and a p-type nitride semiconductor film can be formed by using a silicon-doped gallium nitride target and a magnesium-doped target, respectively, instead of the gallium nitride target.

Finally, the electrode layer 170 is formed on the p-type semiconductor layer 160-p, thereby the light emitting device 100 shown in FIGS. 2A and 2B is manufactured. The electrode layer 170 can be formed by deposition using any method (apparatus) such as sputtering or CVD.

In the method for manufacturing the light emitting device 100 of this embodiment, since it can be manufactured at a lower temperature than the conventional method, it is possible to use a large-area amorphous glass substrate as the substrate 110 and manufacture a plurality of light emitting devices 100 on the substrate 110. Therefore, the manufacturing cost of the light emitting device 100 can be suppressed.

### Third Embodiment

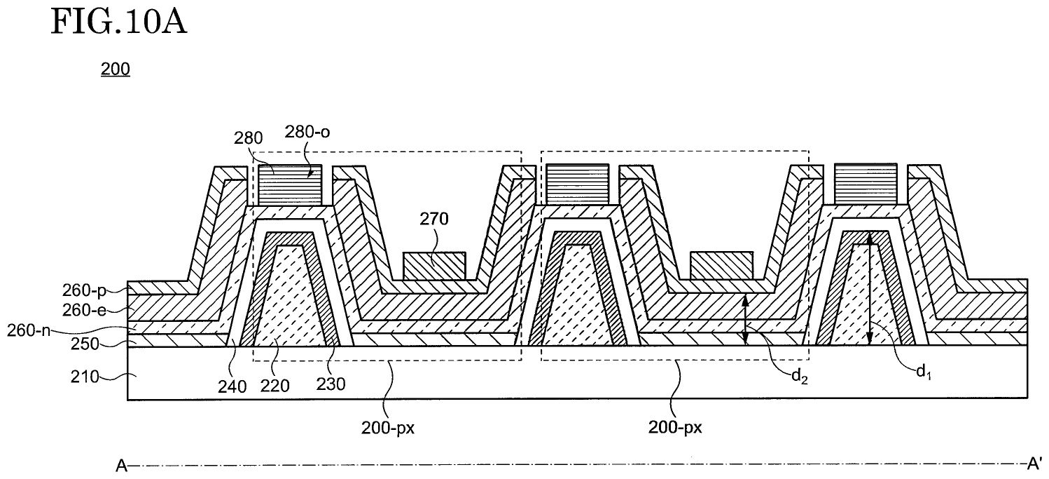

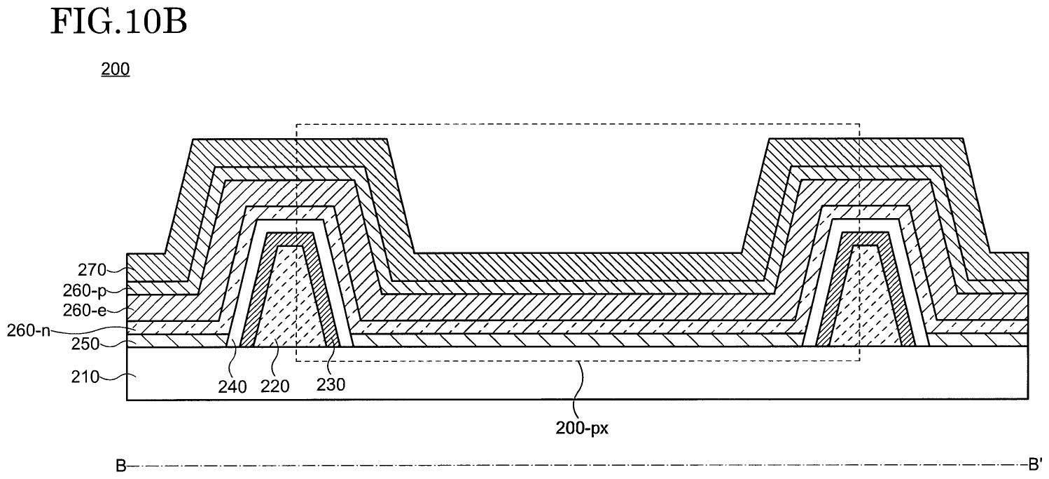

A configuration of a light emitting device 200 according to an embodiment of the present invention is described with reference to FIGS. 10A and 10B. In addition, when a configuration of the light emitting device 200 is similar to the configuration of the light emitting device 100, the description thereof may be omitted.

FIGS. 10A and 10B are schematic cross-sectional views showing a configuration of the light emitting device 200 according to an embodiment of the present invention. Specifically, FIG. 10A is a cross-sectional view of a pixel 200-px cut along the first direction, and FIG. 10B is a cross-sectional view of the pixel 200-px cut along the second direction. As shown in FIG. 10A and FIG. 10B, the light emitting device 200 includes a substrate 210, a partition wall 220, a reflective layer 230, an insulating layer 240, an insulating alignment layer 250, an n-type semiconductor layer 260-n, a light emitting layer 260-e, a p-type semiconductor layer 260-p, a first electrode layer 270, and a second electrode layer 280.

The partition wall 220 is provided on the substrate. In a plan view, the partition wall 220 is provided in a lattice pattern, and includes an opening portion through which the substrate 210 is exposed in each of the pixels 200-px. That is, the pixels 200-px are defined by the partition wall 220 and arranged in a matrix. The partition wall 220 has upper and side surfaces. The side surface of the partition wall 220 is inclined with respect to the substrate 210. The inclination angle of the side surface of the partition wall 220 with respect to the substrate 210 is, for example, greater than or equal to 1 degree and less than or equal to 89 degrees, and preferably greater than or equal to 30 degrees and less than or equal to 60 degrees.

The reflective layer 230 is provided on the substrate 210 and the partition wall 220 so as to cover the upper and side surfaces of the partition wall 220. Further, in a plan view, the reflective layer 230 is provided in a lattice shape, similar to the partition wall 220, and includes an opening portion through which the substrate 210 is exposed in each of the plurality of pixels 200-px.

The insulating layer 240 is provided on the reflective layer 230 so as to cover the reflective layer 230 provided on the upper and side surfaces of the partition wall 220. Further, in the plan view, the insulating layer 240 is provided in a lattice shape and includes an opening portion through which the substrate 110 is exposed in each of the plurality of pixels 200-px.

The insulating alignment layer 250 is provided on the substrate 110 so as to cover the opening portion of the insulating layer 240. Further, in the plan view, the insulating alignment layer 250 is provided in an island shape in each of the plurality of pixels 200-px.

The n-type semiconductor layer 260-n, the light emitting layer 260-e, and the p-type semiconductor layer 260-p are sequentially provided on the insulating alignment layer 250, in common to the plurality of pixels 200-px arranged in a matrix. Further, the light emitting layer 260-e and the p-type semiconductor layer 260-p are opened in a region overlapping the upper surface of the partition wall 220 so that the n-type semiconductor layer 260-n is exposed. That is, an opening portion 280-o is provided in the region overlapping the upper surface of the partition wall 220.

The first electrode layer 270 is provided on the p-type semiconductor layer 260-p so as to overlap the insulating alignment layer 250. The first electrode layer 270 is in contact with the p-type semiconductor layer 260-p. Further, in the plan view, the first electrode layer 270 extends in the second direction and is provided commonly in a plurality of pixels 200-px arranged in the second direction.

The second electrode layer 280 is provided so as to be in contact with the n-type semiconductor layer 260-n at the opening 280-o through which the n-type semiconductor layer 260-n is exposed. Further, in the plan view, the second electrode layer 280 extends in the second direction and is provided commonly in the plurality of pixels 200-px arranged in the second direction.

Next, materials of each component are described.

The substrate 210, the partition wall 220, the reflective layer 230, the insulating layer 240, the n-type semiconductor layer 260-n, the light emitting layer 260-e, and the p-type semiconductor layer 260-p are the same material as the substrate 110, the partition wall 120, the reflective layer 140A, the insulating layer 150, the n-type semiconductor layer 160-n, the light emitting layer 160-e, and the p-type semiconductor layer 160-p, respectively.

The first electrode layer 270 functions as a p-type electrode of the LED. For example, a metal material such as palladium (Pd) or gold (Au) can be used for the first electrode layer 270. Meanwhile, the second electrode layer 280 functions as an n-type electrode of the LED. For example, a metal material such as silver (Ag) or indium (In) or a transparent conductive oxide such as indium tin oxide (ITO), indium zinc oxide (IZO), or zinc oxide (ZnO) can be used for the second electrode layer 280.

In addition, the functions of the first electrode layer 270 and the second electrode layer 280 may be reversed. In this case, the p-type semiconductor layer 260-p, the light emitting layer 260-e, and the n-type semiconductor layer 260-n are sequentially provided on the insulating alignment layer 250.

The insulating alignment layer 250 has insulating properties and can improve the crystallinity of the n-type semiconductor layer 260-n deposited on the insulating alignment layer 250. For example, aluminum nitride (AlN), aluminum oxide (Al₂O₃), lithium niobate (LiNbO), BiLaTiO, SrFeO, SrFeO, BiFeO, BaFeO, ZnFeO, PMnN-PZT, or biological apatite (BAp) can be used as the insulating alignment layer 250. In particular, it is preferable to use aluminum nitride (AlN) for the insulating alignment layer 250.

Each of the plurality of pixels 200-px includes not only the insulating alignment layer 250 for improving crystallinity but also the first electrode layer 270, the p-type semiconductor layer 260-p, the light emitting layer 260-e, the n-type semiconductor layer 260-n, and the second electrode layer 280 as an LED. The first electrode layer 270 and the second electrode layer 280 extend in the second direction. Therefore, in the light emitting device 200, light emission from the plurality of pixels 200-px arranged in the second direction can be controlled as one unit.

In the light emitting device 200, the n-type semiconductor layer 260-n is in contact with the insulating alignment layer 250 in a region where the partition wall 220 is not provided (or a region not overlapping the partition wall 120, hereinafter referred to as a “non-partition-formed region”). Therefore, the crystallinity of the n-type semiconductor layer 260-n is improved in the non-partition-formed region. Further, the crystallinity of not only the n-type semiconductor layer 260-n but also the light emitting layer 260-e and the p-type semiconductor layer 260-p is improved in the non-partition-formed region. Therefore, in the light emitting device 200, the light emission intensity from the light emitting layer 260-e is increased in the non-partition-formed region.

Further, in the light emitting device 200, the distance d₁ from the upper surface of the substrate 210 to the upper surface of the reflective layer 230 in a region where the partition wall 220 is provided (or a region overlapping the partition wall 220, hereinafter referred to as the “partition-formed region”) is greater than the distance d₂ from the upper surface of the substrate 210 to the upper surface of the light emitting layer 260-e in the non-partition-formed region. Therefore, the light emitted from the side surface of the light emitting layer 260-e is reflected toward the upper surface of the light emitting device 200 by the reflective layer 230 provided on the side surface of the partition wall 220. Accordingly, in the light emitting device 200, the light extraction efficiency in the upper surface direction is increased, and the light emission efficiency in the upper surface direction can be improved.

### Modification 1 of Third Embodiment

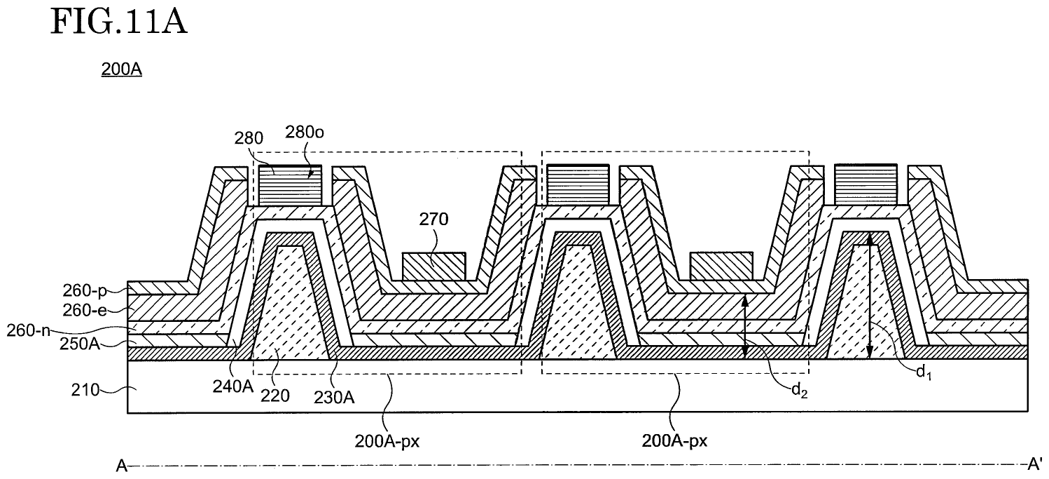

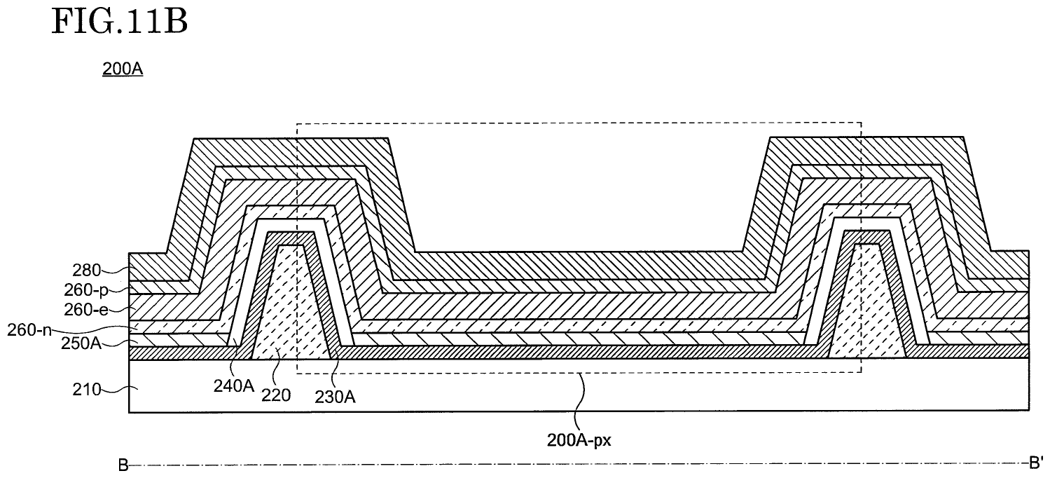

A light emitting device 200A, which is one of the modifications of the light emitting device 200 is described with reference to FIGS. 11A and 11B. When a configuration of the light emitting device 200A is similar to the configuration of the light emitting device 200, the description thereof may be omitted.

FIGS. 11A and 11B are cross-sectional views showing a configuration of the light emitting device 200A according to an embodiment of the present invention. Specifically, FIG. 11A is a cross-sectional view of a pixel 200A-px cut along the first direction, and FIG. 11B is a cross-sectional view of the pixel 200A-px cut along the second direction. As shown in FIGS. 11A and 11B, the light emitting device 200A includes the substrate 210, the partition wall 220, a reflective layer 230A, an insulating layer 240A, an insulating alignment layer 250A, the n-type semiconductor layer 260-n, the light emitting layer 260-e, the p-type semiconductor layer 260-p, the first electrode layer 270, and the second electrode layer 280.

The reflective layer 230A covers the upper and side surfaces of the partition wall 220, and is provided on the substrate 210 and the partition wall 220. The reflective layer 230A is provided commonly in the plurality of pixels 200A-px arranged in a matrix.

The insulating layer 240A is provided on the reflective layer 230A so as to cover the reflective layer 230A provided on the upper and side surfaces of the partition wall 220. Further, in a plan view, the insulating layer 240A is provided in a lattice shape, similar to the partition wall 220, and includes an opening portion through which the reflective layer 230A is exposed in each of the plurality of pixels 200A-px.

The insulating alignment layer 250A is provided on the reflective layer 230A so as to cover the opening portion of the insulating layer 240A. Further, in the plan view, the insulating alignment layer 250A is provided in an island shape in each of the plurality of pixels 200A-px.

Each of the pixels 200A-px includes not only the insulating alignment layer 250A for improving crystallinity but also the first electrode layer 270, the p-type semiconductor layer 260-p, the light emitting layer 260-e, the n-type semiconductor layer 260-n, and the second electrode layer 280 as an LED. The first electrode layer 270 and the second electrode layer 280 extend in the second direction. Therefore, in the light emitting device 200A, light emission from the plurality of pixels 200A-px arranged in the second direction can be controlled as one unit.

In the light emitting device 200A, the n-type semiconductor layer 260-n is in contact with the insulating alignment layer 250A in the non-partition-formed region. Therefore, the crystallinity of the n-type semiconductor layer 260-n is improved in the non-partition-formed region. Further, the crystallinity of not only the n-type semiconductor layer 260-n but also the light emitting layer 260-e and the p-type semiconductor layer 260-p is improved in the non-partition-formed region. Therefore, in the light emitting device 200A, the light emission intensity from the light emitting layer 260-e is increased in the non-partition-formed region.

Further, the distance d₁ from the upper surface of the substrate 210 to the upper surface of the reflective layer 230A in the partition-formed region is greater than the distance d₂ from the upper surface of the substrate 210 to the upper surface of the light emitting layer 260-e in the non-partition-formed region. Therefore, the light emitted from the side surface of the light emitting layer 260-e is reflected toward the upper surface of the light emitting device 200A by the reflective layer 230A provided on the side surface of the partition wall 220. Accordingly, in the light emitting device 200A, the light extraction efficiency in the upper surface direction is increased, and the light emission efficiency in the upper surface direction can be improved.

Furthermore, the reflective layer 230A is also provided below the insulating alignment layer 250A in the light emitting device 200A. Therefore, when the insulating alignment layer 250A has light-transmitting properties, the light emitted from the lower surface of the light emitting layer 260-e is reflected toward the upper surface of the light emitting device 200A by the reflective layer 230A below the insulating alignment layer 250A. Accordingly, in the light emitting device 200A, the reflection efficiency can be increased, and the light emission efficiency in the upper surface direction can be further improved.

### Modification 2 of Third Embodiment

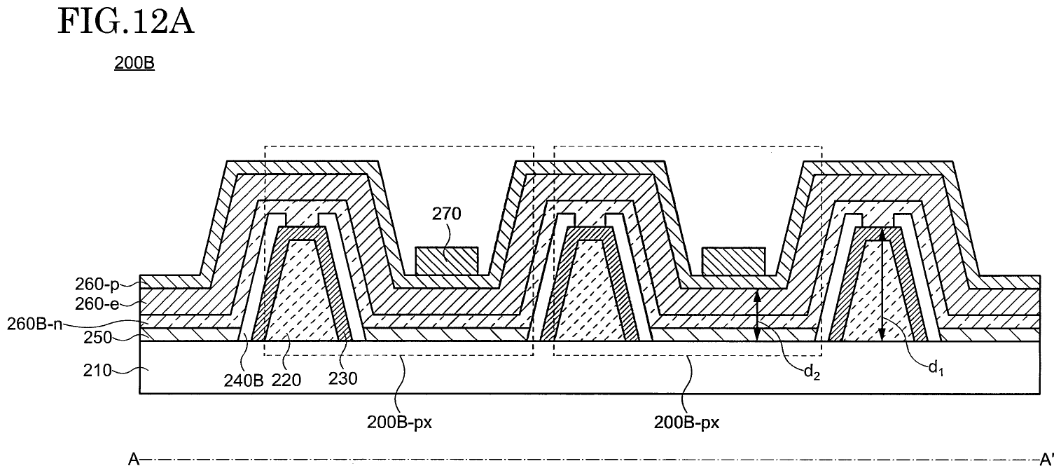

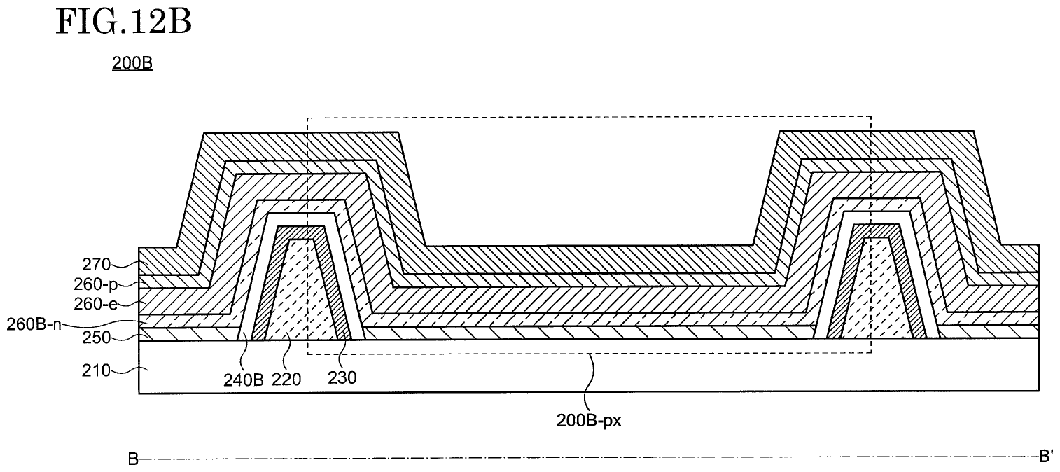

A light emitting device 200B, which is one of the modifications of the light emitting device 200 is described with reference to FIGS. 12A and 12B. In addition, when a configuration of the light emitting device 200B is similar to the configuration of the light emitting device 200, the description thereof may be omitted.

FIGS. 12A and 12B are cross-sectional views showing a configuration of the light emitting device 200A according to an embodiment of the present invention. Specifically, FIG. 12A is a cross-sectional view of a pixel 200B-px cut along the first direction, and FIG. 12B is a cross-sectional view of the pixel 200B-px cut along the second direction. As shown in FIG. 12A and FIG. 12B, the light emitting device 200B includes the substrate 210, the partition wall 220, the reflective layer 230, an insulating layer 240B, the insulating alignment layer 250, an n-type semiconductor layer 260B-n, the light emitting layer 260-e, the p-type semiconductor layer 260-p, and the first electrode layer 270.

The insulating layer 240B is provided on the substrate 210 and the reflective layer 230 so as to cover the reflective layer 230 provided on the side surface of the partition wall 220. Further, in a plan view, the insulating layer 240B is provided in a lattice shape, and includes an opening portion through which the substrate 210 is exposed in each of the plurality of pixels 200B-px, similar to the partition wall 220. Furthermore, the insulating layer 240B includes an opening portion through which the reflective layer 230 on the upper surface of the partition wall 220 is exposed in each of the plurality of pixels 200B-px.

The n-type semiconductor layer 260B-n is provided commonly in the plurality of pixels 200B-px arranged in a matrix. The n-type semiconductor layer 260B-n is in contact with the reflective layer 230 through the opening portion through which the reflective layer 230 is exposed.

Each of the pixels 200B-px includes not only the insulating alignment layer 250B for improving crystallinity but also the first electrode layer 270, the p-type semiconductor layer 260-p, the light emitting layer 260-e, the n-type semiconductor layer 260B-n, and the reflective layer 230 as an LED. Here, one of the electrodes of the LED is the first electrode layer 270, and the other of the electrodes of the LED is the reflective layer 230. The first electrode layer 270 extends in the second direction and is provided on a plurality of pixels 200B-px arranged in the second direction. Further, the reflective layer 230 is provided commonly in the plurality of pixels 200B-px arranged in a matrix. Therefore, in the light emitting device 2000, light emission from the plurality of pixels 200B-px arranged in the second direction can be controlled as one unit.

In the light emitting device 200B, the n-type semiconductor layer 260B-n is in contact with the insulating alignment layer 250 in the non-partition-formed region. Therefore, the crystallinity of the n-type semiconductor layer 260B-n is improved in the non-partition-formed region. Further, the crystallinity of not only the n-type semiconductor layer 260B-n but also the light emitting layer 260-e and the p-type semiconductor layer 260-p is improved in the non-partition-formed region. Therefore, in the light emitting device 200B, the light emission intensity from the light emitting layer 260-e is increased in the non-partition-formed region.

Further, in the light emitting device 200B, the distance d₁ from the upper surface of the substrate 210 to the upper surface of the reflective layer 230 in the partition-formed region is greater than the distance d₂ from the upper surface of the substrate 210 to the upper surface of the light emitting layer 260-e in the non-partition-formed region. Therefore, the light emitted from the side surface of the light emitting layer 260-e is reflected toward the upper surface of the light emitting device 200 by the reflective layer 230 provided on the side surface of the partition wall 220. Accordingly, in the light emitting device 200B, the light extraction efficiency in the upper surface direction is increased, and the light emission efficiency in the upper surface direction can be improved.

Furthermore, in the light emitting device 200B, the reflective layer 230 and the n-type semiconductor layer 260B-n are in contact with each other through the opening portion formed in the insulating layer 240B in the partition-formed region. Therefore, the conductive reflective layer 230 can function as the n-type electrode of the LED. Accordingly, in the light emitting device 200B, since it is not required to provide another n-type electrode, the manufacturing cost of the light emitting device 200B can be reduced.

### Modification 3 of Third Embodiment

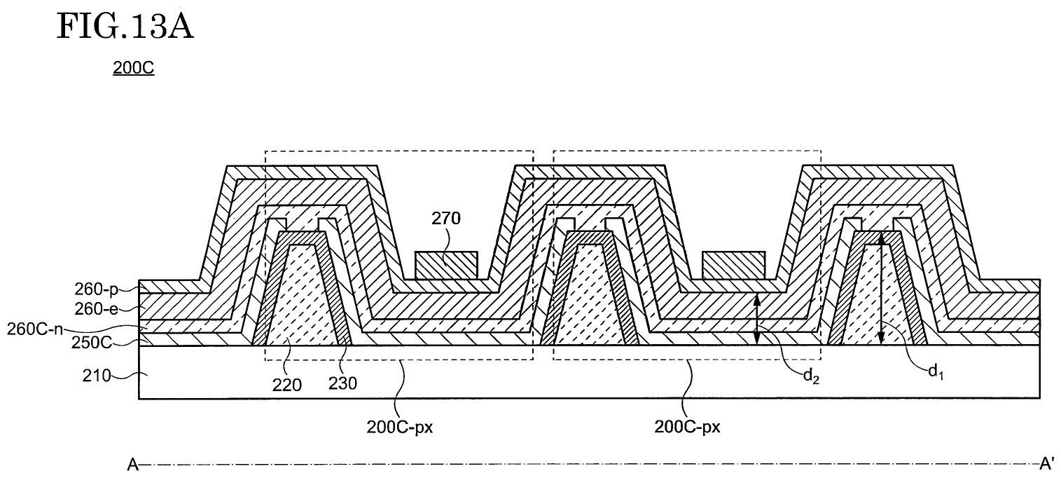

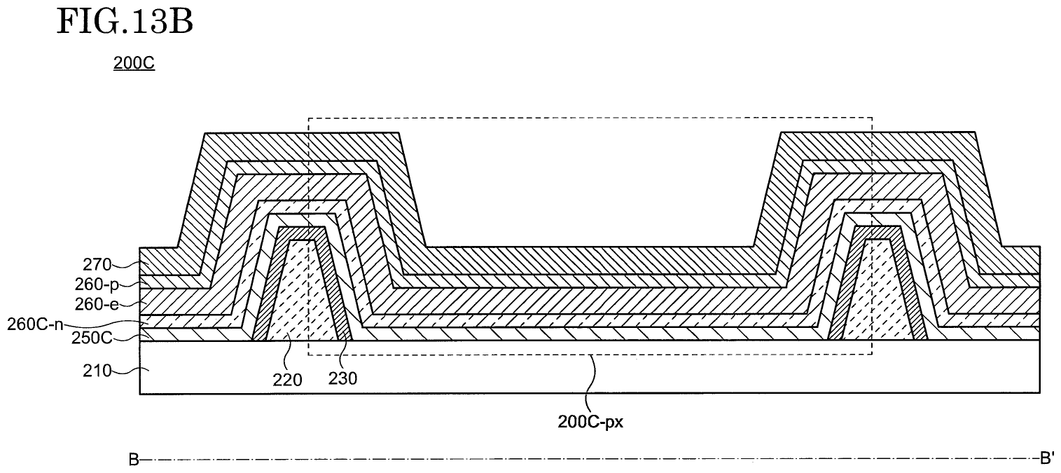

A light emitting device 2000, which is one of the modifications of the light emitting device 200 is described with reference to FIGS. 13A and 13B. In addition, when a configuration of the light emitting device 2000 is similar to the configuration of the light emitting device 200, the description thereof may be omitted.

FIGS. 13A and 13B are cross-sectional views showing a configuration of the light emitting device 2000 according to an embodiment of the present invention. Specifically, FIG. 13A is a cross-sectional view of a pixel 2000-px cut along the first direction, and FIG. 13B is a cross-sectional view of the pixel 2000-px cut along the second direction. As shown in FIGS. 13A and 13B, the light emitting device 2000 includes the substrate 210, the partition wall 220, the reflective layer 230, an insulating alignment layer 250C, an n-type semiconductor layer 260C-n, the light emitting layer 260-e, the p-type semiconductor layer 260-p, and the first electrode layer 270.

The insulating alignment layer 250C is provided on the substrate 210 and the reflective layer 230 so as to cover the reflective layer 230 provided on the side surface of the partition wall 220. The insulating alignment layer 250C is provided commonly in the plurality of pixels 2000-px arranged in a matrix. The insulating alignment layer 250C includes an opening portion through which the reflective layer 230 on the upper surface of the partition wall 220 is exposed in each of the plurality of pixels 2000-px.

The n-type semiconductor layer 260C-n is provided commonly in the plurality of pixels 2000-px arranged in a matrix. The n-type semiconductor layer 260C-n is in contact with the reflective layer 230 through the opening portion of the insulating alignment layer 250C through which the reflective layer 230 is exposed.

The reflective layer 230 and the n-type semiconductor layer 260C-n are separated by the insulating alignment layer 250C. Although the insulating layer 240B of the light emitting device 200B is not provided in the light emitting device 2000, the insulating alignment layer 250C has the same function as the insulating layer 240B. In other words, the insulating alignment layer 230C of the light emitting device 2000 is configured to be the same layer and the same material as the insulating alignment layer 240B in the light emitting device 200B.

Each of the pixels 2000-px includes the insulating alignment layer 250C for improving crystallinity, and the first electrode layer 270, the p-type semiconductor layer 260-p, the light emitting layer 260-e, the n-type semiconductor layer 260C-n, and the reflective layer 230 as an LED. Here, one of the electrodes of the LED is the first electrode layer 270, and the other of the electrodes of the LED is the reflective layer 230. The first electrode layer 270 extends in the second direction and is provided in a plurality of pixels 2000-px arranged in the second direction. Further, the reflective layer 230 is provided commonly in the plurality of pixels 2000-px arranged in a matrix. Therefore, in the light emitting device 2000, light emission from the plurality of pixels 2000-px arranged in the second direction can be controlled as one unit.

In the light emitting device 2000, the insulating alignment layer 250C and the n-type semiconductor layer 260C-n are in contact with each other even on the side surface of the partition wall 220. Therefore, the crystallinity of the n-type semiconductor layer 260C-n provided not only in the non-partition-formed region but also on the side surface of the partition wall 220 is improved. Further, the crystallinity is improved not only in the n-type semiconductor layer 260C-n but also in the light emitting layer 260-e and the p-type semiconductor layer 260-p. Therefore, in the light emitting device 2000, the light emission intensity from the light emitting layer 260-e is increased.

In the light emitting device 2000, the distance d₁ from the upper surface of the substrate 210 to the upper surface of the reflective layer 230 in the partition-formed region is greater than the distance d₂ from the upper surface of the substrate 210 to the upper surface of the light emitting layer 260-e in the non-partition-formed region. Therefore, the light emitted from the side surface of the light emitting layer 260-e is reflected toward the upper surface of the light emitting device 200 by the reflective layer 230 provided on the side surface of the partition wall 220. Accordingly, in the light emitting device 2000, the light extraction efficiency in the upper surface direction is increased, and the light emission efficiency in the upper surface direction can be improved.

Further, in the light emitting device 2000, the reflective layer 230 is in contact with the n-type semiconductor layer 260C-n in the partition-formed region. Therefore, the conductive reflective layer 230 can function as an n-type electrode of the LED. Accordingly, in the light emitting device 2000, since it is not required to provide another n-type electrode, the manufacturing cost of the light emitting device 2000 can be reduced.

Furthermore, in the light emitting device 2000, since it is not required to provide another insulating layer to cover the reflective layer 230, the manufacturing cost of the light emitting device 2000 can be further reduced.

### Fourth Embodiment

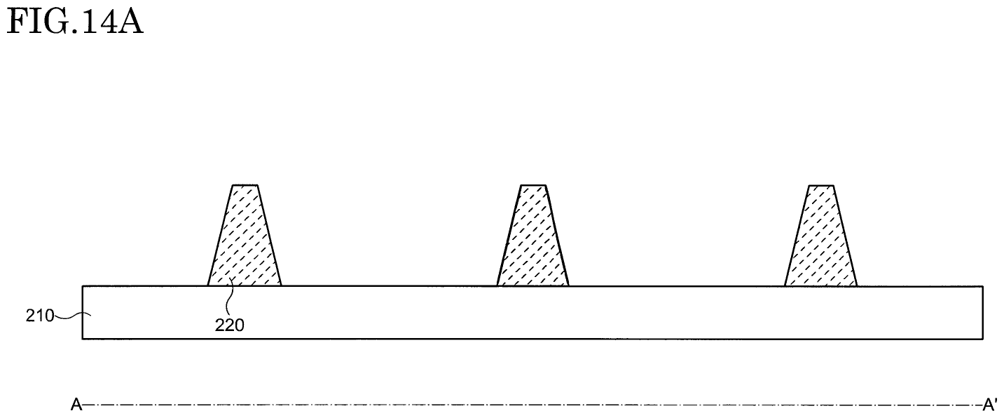

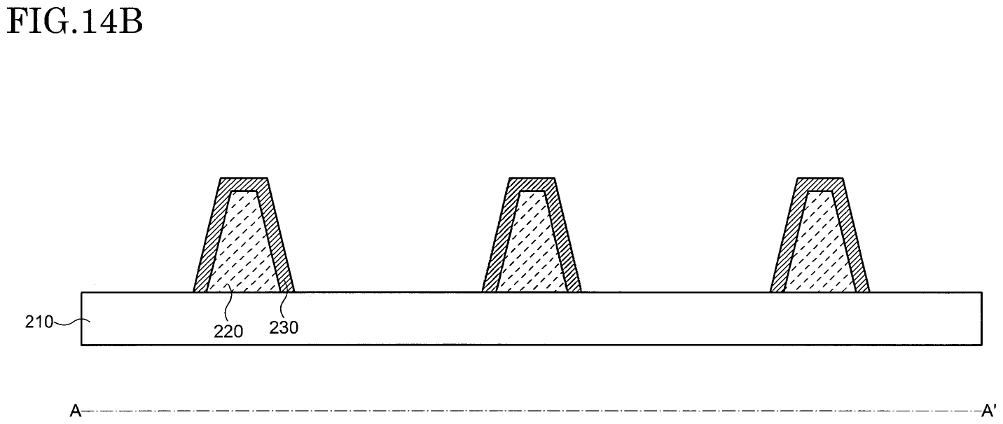

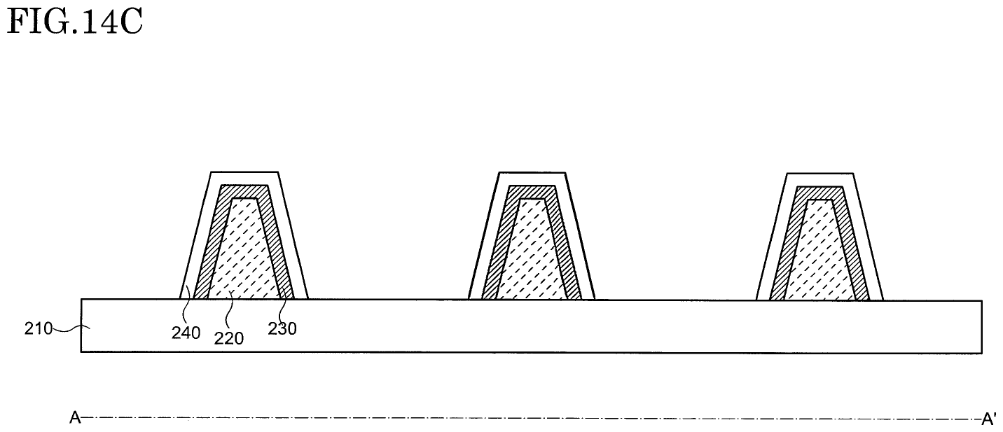

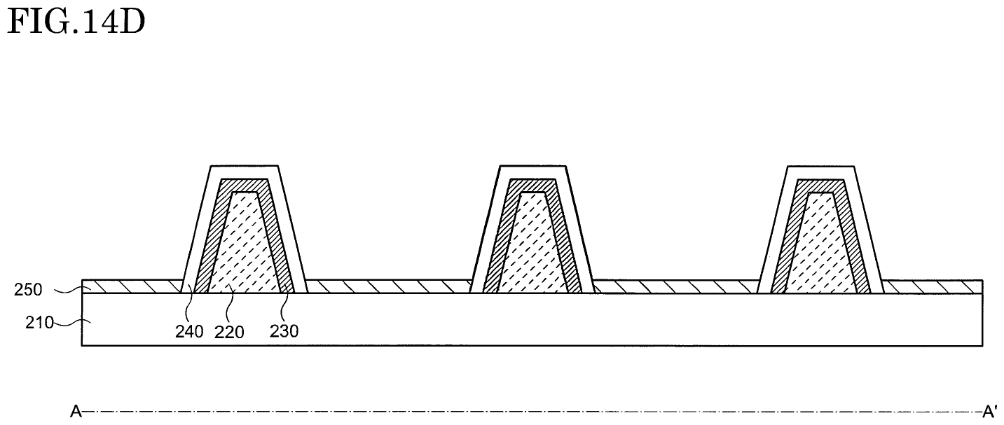

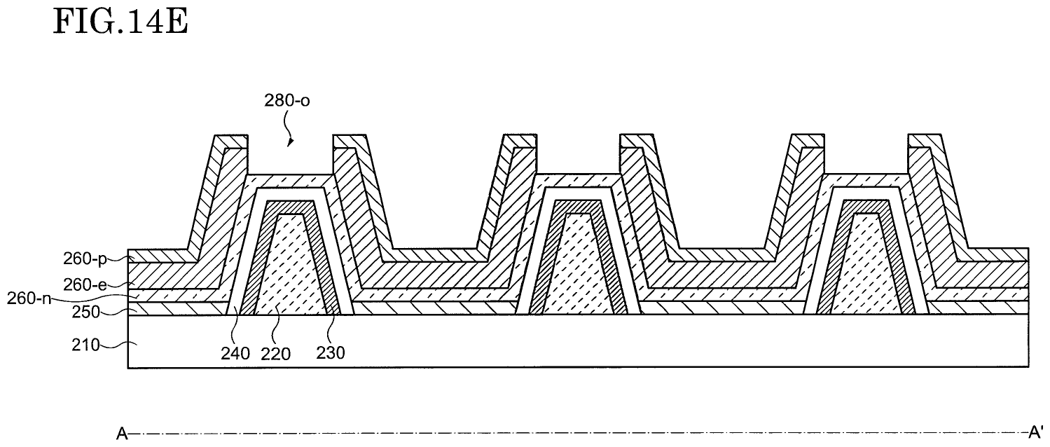

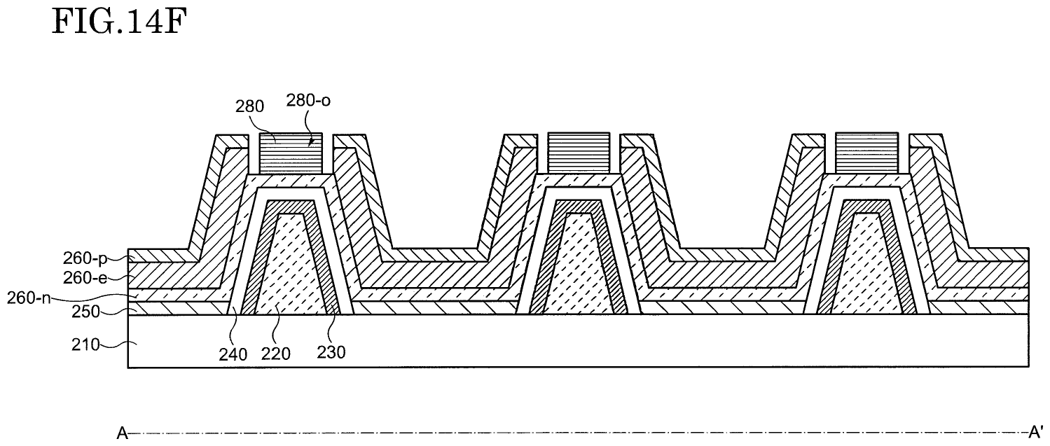

A method for manufacturing the light emitting device 200 according to an embodiment of the present invention is described with reference to FIGS. 14A to 14F. FIGS. 14A to 14F are schematic cross-sectional views showing a method for manufacturing the light emitting device 200 according to an embodiment of the present invention.

First, as shown in FIG. 14A, the partition wall 220 including the opening portion through which the substrate 110 is exposed is formed on the substrate 210. The partition wall 220 is formed by depositing an inorganic material or an organic material and patterning the inorganic material or the organic material using photolithography. In addition, the patterning may be performed using a halftone mask or a gray-tone mask in order to form the partition wall 220 having an inclined side surface.

Next, as shown in FIG. 14B, the reflective layer 230 is formed to cover the upper and side surfaces of the partition wall 220 and to include the opening portion through which the substrate 110 is exposed. The reflective layer 230 can be formed by depositing a film using any method (apparatus) such as sputtering or CVD, and patterning the film using photolithography.

Next, as shown in FIGS. 14C, the insulating layer 240 is formed to cover the reflective layer 230 and to include the opening portion through which the substrate 110 is exposed. The insulating layer 240 is formed by depositing an inorganic material and patterning the inorganic material using photolithography.

Next, as shown in FIG. 14D, the insulating alignment layer 250 is formed to cover the opening portion through which the substrate 210 is exposed. The insulating alignment layer 250 can be formed by depositing the film using any method (apparatus) such as sputtering or CVD, and patterning the film using photolithography.

Next, as shown in FIG. 14E, the n-type semiconductor layer 260-n, the light emitting layer 260-e, and the p-type semiconductor layer 260-p are sequentially formed so as to cover the insulating layer 240 and the insulating alignment layer 250. Each of the n-type semiconductor layer 260-n, the light emitting layer 260-e, and the p-type semiconductor layer 260-p can be formed by deposition using sputtering. Further, the opening portion 280-o is formed in the region where the light emitting layer 260-e and the p-type semiconductor layer 260-p overlap the upper surface of the partition wall 220. In addition, the region overlapping the opening portion of the insulating layer 240 in the n-type semiconductor layer 260-n, the light emitting layer 260-e, and the p-type semiconductor layer 260-p has high crystallinity because it is formed on the insulating alignment layer 250.

Next, as shown in FIG. 14F, the second electrode layer 280 is formed in the opening portion 280-o. The second electrode layer 280 can be formed by depositing a film using any method (apparatus) such as sputtering or CVD, and patterning the film using photolithography. Further, in the step shown in FIG. 14F, the first electrode layer 270 may be formed simultaneously with the second electrode layer 280.

Finally, the first electrode layer 270 is formed on the p-type semiconductor layer 260-p so as to overlap the opening portion of the insulating layer 240. In this way, the light emitting device 200 shown in FIGS. 10A and 10B is manufactured. The first electrode layer 270 can be formed by deposition using any method (apparatus) such as sputtering or CVD.

In the method for manufacturing the light emitting device 200 of this embodiment, since it can be manufactured at a lower temperature than the conventional method, it is possible to use a large-area amorphous glass substrate as the substrate 210 and manufacture a plurality of light emitting devices 100 on the substrate 210. Therefore, the manufacturing cost of the light emitting device 200 can be suppressed.

### Fifth Embodiment

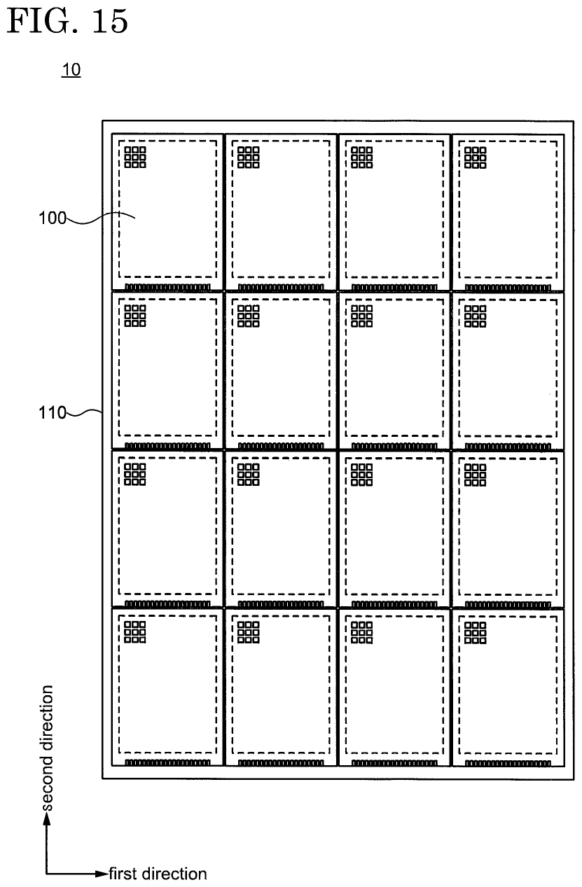

A light emitting device forming substrate 10 according to an embodiment of the present invention is described with reference to FIG. 15.

FIG. 15 is a schematic diagram showing a configuration of the light emitting device formation substrate 10 according to an embodiment of the present invention. The light emitting device formation substrate 10 includes the plurality of light emitting devices 100. That is, in the light emitting device formation substrate 10, the plurality of light emitting devices 100 are manufactured using one substrate 110. The substrate 110 is a so-called large-area substrate. In the light emitting device formation substrate 10, the plurality of light emitting devices 100 can be manufactured at once using a large-area substrate, so that the manufacturing cost of the light emitting devices 100 can be suppressed.

In addition, although the light emitting device 100 described in the First Embodiment is described as an example, the light emitting devices (100A, 100B, 1000, 100D, 100E, 200, 200A, 200B, and 2000) described in other embodiments (including modifications) are also applied to the configuration of the present embodiment.

Each of the embodiments described above as an embodiment of the present invention can be appropriately combined and implemented as long as they do not contradict each other. Additions, deletions, or design changes of constituent elements, or additions, omissions, or changes to conditions of steps as appropriate based on the respective embodiments are also included within the scope of the present invention as long as the gist of the present invention is provided.

Other effects which differ from those brought about by each of the embodiments described above, but which are apparent from the description herein or which can be readily predicted by those skilled in the art, are naturally understood to be brought about by the present invention.

What is claimed is:

1. A light emitting device comprising:
a substrate;
a partition wall over the substrate, the partition wall defining a plurality of pixels in a matrix in a first direction and in a second direction orthogonal to the first direction;
a reflective layer covering the partition wall; and
an insulating layer covering the reflective layer,
wherein each of the plurality of pixels arranged in a matrix comprises:
a conductive alignment layer over the substrate,
a semiconductor layer comprising gallium nitride over the conductive alignment layer,
a light emitting layer over the semiconductor layer, and
an electrode layer over the light emitting layer,
a distance from an upper surface of the substrate to an upper surface of the reflective layer in a region overlapping the partition wall is greater than a distance from the upper surface of the substrate to an upper surface of the light emitting layer in a region not overlapping the partition wall.

2. The light emitting device according to claim 1, wherein the insulating layer comprises an opening portion in each of the plurality of pixels arranged in a matrix.

3. The light emitting device according to claim 1, wherein the semiconductor layer is provided commonly in the plurality of pixels arranged in a matrix.

4. The light emitting device according to claim 1, wherein the reflective layer is a same layer as the conductive alignment layer.

5. The light emitting device according to claim 1, wherein the conductive alignment layer is provided between the substrate and the partition wall.

6. The light emitting device according to claim 1, wherein the conductive alignment layer is provided in an island shape.

7. The light emitting device according to claim 1,
wherein the electrode layer extends in the first direction and is provided commonly in a plurality of pixels arranged in the first direction, and
the conductive alignment layer extends in the second direction and is provided commonly in a plurality of pixels arranged in the second direction.

8. The light emitting device according to claim 1, wherein the reflective layer and the insulating layer are provided commonly in the plurality of pixels arranged in a matrix.

9. The light emitting device according to claim 1, wherein the conductive alignment layer comprises at least one of titanium and titanium nitride.

10. A light emitting device comprising:
a substrate;
a partition wall over the substrate, the partition wall defining a plurality of pixels in a matrix in a first direction and in a second direction orthogonal to the first direction;
a reflective layer covering the partition wall; and
an insulating layer covering the reflective layer,
wherein each of the plurality of pixels arranged in a matrix comprises:
an insulating alignment layer over the substrate,
a semiconductor layer comprising gallium nitride over the insulating alignment layer,
a light emitting layer over the semiconductor layer, and
a first electrode layer over the light emitting layer,
a distance from an upper surface of the substrate to an upper surface of the reflective layer in a region overlapping the partition wall is greater than a distance from the upper surface of the substrate to an upper surface of the light emitting layer in a region not overlapping the partition wall.

11. The light emitting device according to claim 10,
wherein each of the plurality of pixels further comprises a second electrode layer, and
the second electrode layer is in contact with the semiconductor layer through an opening portion in the light emitting layer.

12. The light emitting device according to claim 10, wherein the semiconductor layer is in contact with the reflective layer through an opening portion in the insulating layer.

13. The light emitting device according to claim 1, wherein the insulating layer comprises an opening portion in each of the plurality of pixels arranged in a matrix.

14. The light emitting device according to claim 10, wherein the semiconductor layer is provided commonly in the plurality of pixels arranged in a matrix.

15. The light emitting device according to claim 10, wherein the reflective layer is provided commonly in the plurality of pixels arranged in a matrix.

16. The light emitting device according to claim 10, wherein the insulating alignment layer is provided in an island shape.

17. The light emitting device according to claim 10, wherein the insulating layer is a same layer as the insulating alignment layer.

18. The light emitting device according to claim 10, wherein the insulating alignment layer comprises at least one of aluminum nitride and aluminum oxide.
